(19) United States
(12) Patent Application Publication
(10) Pub. No.: US 2019/0185495 A1
(43) Pub. Date: Jun. 20, 2019

(54) PROCESS FOR THE PREPARATION OF HALIDE PEROVSKITE AND PEROVSKITE-RELATED MATERIALS

(71) Applicant: YE DA RESEARCH AND DEVELOPMENT CO. LTD., Rehovot (IL)

(72) Inventors: David CAHEN, Rehovot (IL); Gary MODES, Rehovot (IL); Yevgeny RAKITA, Rehovot (IL); Nir KEDEM, Rehovot (IL)

(73) Assignee: YE DA RESEARCH AND DEVELOPMENT CO. LTD., Rehovot (IL)

(21) Appl. No.: 16/099,697

(22) PCT Filed: May 8, 2017
(86) PCT No.: PCT/IL2017/050503

§ 371 Date: Nov. 8, 2018

(30) Foreign Application Priority Data
May 8, 2016 (IL) 245536

(51) Int. Cl. C07F 7/24; C07F 7/22; C01G 21/16; H01L 51/00

(52) U.S. Cl. CPC C07F 7/24; C07F 7/2288; H01L 51/4226; C01G 21/16; H01L 51/005; C07F 7/2284

(57) ABSTRACT

This invention is related to a method for the preparation of halide perovskite or perovskite-related materials on a substrate and to optoelectronic devices and photovoltaic cells comprising the perovskites prepared by the methods of this invention The method for the preparation of the perovskite includes a direct conversion of elemental metal or metal alloy to halide perovskite or perovskite-related materials.

### FIELD OF THE INVENTION

This invention is related to a method for the preparation of halide perovskite or perovskite-related materials on a substrate and to optoelectronic devices and photovoltaic cells comprising the perovskites prepared by the methods of this invention. The method for the preparation of the perovskite includes a direct conversion of elemental metal or metal alloy to halide perovskite or perovskite-related materials.

### BACKGROUND OF THE INVENTION

Halide perovskite semiconductors have demonstrated unusual rapid progress in photovoltaic performance, now surpassing 20% conversion efficiency. While these materials have been known for a long time, it is only in the past ˜25 years that they have been seriously considered as electronic materials, in particular as light-emitting devices and transistors [1] while their entry into photovoltaic research occurred only a few years ago (2012) [2-5].

The most studied material is MAPbI₃ since this material has a bandgap (˜1.6 eV) close to that needed for an optimal single junction solar (photovoltaic) cell. (MA refers to methylammonium, CH₃NH₃⁺ abbreviated to MA). The higher bandgap MAPbBr₃ (˜2.3 eV) has also attracted much attention as a high bandgap semiconductor for use in spectrally-split photovoltaic cells (e.g. tandem cells) or for production of chemicals by photoelectrochemical processes.

The high photovoltaic and optoelectronic performance of these materials arises from a combination of properties such as large diffusion lengths of photogenerated electrons and holes (due to a combination of long charge lifetimes and good charge mobilities); high optical absorption coefficients and low trap densities.

There are several general methods used to make layers of these semiconductors:

1. spin-coating from organic solutions of the semiconductors or precursors;
2. vacuum evaporation; or
3. spray-coating.

The spin-coating from organic solutions is particularly popular since it requires relatively simple equipment and low temperature (energy) input (important for future manufacturing processes). The solution method is a one-step method or a two-step method.

The one-step method for the preparation MAPbI₃ includes for example: a solution containing MAI and PbI₂ in polar solvents spin-coated onto the desired substrate. [6]

The two-step method for the preparation of MAPbI₃ includes for example: a solution of PbI₂ is first spin-coated onto the substrate. This PbI₂ layer is then converted to MAPbI₃ by treatment with MAI, either in solution or by MAI vapor. [4,7]

In both spin-coating methods, the final layer is most often given a heat treatment at typically 100-130° C. The spin-coating method further may include different treatments, for example, adding a non-solvent during the spin-coating [8] and annealing in the presence of solvent vapor [9].

The organic solvents used in these depositions are mostly toxic: dimethyl formamide (DMF) is the most commonly used one; dimethyl sulfoxide (DMSO), which, while not toxic by itself, becomes very much so when it contains dissolved Pb salts; gamma butyrolactone (GBL)). Therefore toxicity would be an important consideration at the manufacturing stage, which could increase considerably the manufacturing costs.

The vacuum evaporation may include multiple sources with a high level of control over the evaporation rate of each precursor. This method is, though, less popular mainly due to its higher level of complexity and high-energy input.

The spray coating usually includes a single source with high level of control over the spraying rate and substrate temperature. Very often the sprayed liquid is very toxic, which is the case with spray coating of perovskites. Usually such systems require high level of isolation from the environment.

### REFERENCES

1. (i) Mitzi, D. B. in Prog. Inorg. Chem. (ed. Karlin, K. D.) 1-121 (John Wiley & Sons, Inc., 1999)|DOI:10.1002/9780470166499.ch1; (ii) David B. Mitzi, Templating and structural engineering in organic-inorganic Perovskites, J. Chem. Soc., Dalton Trans., 2001, 1-12|DOI:10.1039/B007070J
2. Liu, M., Johnston, M. B. & Snaith, H. J. Efficient planar heterojunction perovskite solar cells by vapour deposition. Nature 501, 395-398 (2013).
3. Kim, H.-S., Lee, C.-R., Im, J.-H., Lee, K.-B., Moehl, T., Marchioro, A., Moon, S.-J., Humphry-Baker, R., Yum, J.-H., Moser, J. E., Griitzel, M. & Park, N.-G. Lead Iodide Perovskite Sensitized All-Solid-State Submicron Thin Film Mesoscopic Solar Cell with Efficiency Exceeding 9%. Sci. Rep. 2, (2012).
4. Burschka, J., Pellet, N., Moon, S.-J., Humphry-Baker, R., Gao, P., Nazeeruddin, M. K. & Grätzel, M. Sequential deposition as a route to high-performance perovskite-sensitized solar cells. Nature 499, 316-319 (2013).
5. Green, M. A., Emery, K., Hishikawa, Y., Warta, W. & Dunlop, E. D. Solar cell efficiency tables (version 47). Prog. Photovolt. Res. Appl. 24, 3-11 (2016).
6. Kojima, A., Teshima, K., Shirai, Y. & Miyasaka, T. Organometal Halide Perovskites as Visible-Light Sensitizers for Photovoltaic Cells. J. Am. Chem. Soc. 131, 6050-6051 (2009).
7. Chen, Q., Zhou, H., Hong, Z., Luo, S., Duan, H.-S., Wang, H.-H., Liu, Y., Li, G. & Yang, Y. Planar Heterojunction Perovskite Solar Cells via Vapor-Assisted Solution Process. J. Am. Chem. Soc. 136, 622-625 (2014).
8. Jeon, N. J., Noh, J. H., Kim, Y. C., Yang, W. S., Ryu, S. & Seok, S. I. Solvent engineering for high-performance inorganic-organic hybrid perovskite solar cells. Nat. Mater. 13, 897-903 (2014).
9. Liu, J., Gao, C., He, X., Ye, Q., Ouyang, L., Zhuang, D., Liao, C., Mei, J. & Lau, W. Improved Crystallization of Perovskite Films by Optimized Solvent Annealing for High Efficiency Solar Cell. ACS Appl. Mater. Interfaces 7, 24008-24015 (2015).

### SUMMARY OF THE INVENTION

In one embodiment, this invention provides a method for the preparation of halide perovskite or perovskite-related materials of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a perovskite or perovskite-related material;
wherein the inorganic cation of A is different from the metal cation of B;
wherein said method comprises:
depositing a layer of metal or metal alloy of B on a substrate; and
   treating said layer of metal or metal alloy of B with a solution or vapor containing A and X wherein said solution or vapor reacts with said metal or metal alloy of B to form a halide perovskite or perovskite-related material of formula AᵤBᵥX_{w} on said solid surface;
   or
depositing a layer of a salt comprising A and X on a substrate; and
   treating said layer of salt with a vapor of metal or metal alloy of B; wherein said metal or metal alloy of B reacts with said salt to form a halide perovskite or perovskite-related material of formula AᵤBᵥX_{w} on said solid surface.

In one embodiment, this invention provides a halide perovskite or perovskite-related material prepared according to the methods of this invention.

In one embodiment, this invention provides an optoelectronic device comprising a halide perovskite or perovskite-related material of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite related materials;
wherein the inorganic cation of A is different from the metal cation of B;
wherein said halide perovskite or related perovskite material of formula AᵤBᵥX_{w} is prepared according to the methods of this invention.

In one embodiment, this invention provides a photovoltaic cell comprising a halide perovskite or perovskite-related material of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite related materials;
wherein the inorganic cation of A is different from the metal cation of B;
wherein said halide perovskite or perovskite-related material of formula AᵤBᵥX_{w} is prepared according to the methods of this invention.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1D present evaporated Pb on glass slide. Cross-section-view (FIG. 1A) and plan-view (FIG. 1B) SEM images of ˜50 nm evaporated Pb on a glass slide. X-ray diffraction of ˜50 nm Pb-evaporated film on a glass slide (FIG. 1C). Image of evaporated Pb on a glass slide (FIG. 1D).

FIGS. 2A-2E present the reaction process of Pb film with MABr, MAI or FAI. FIG. 2A: Reaction of Pb films (˜120 nm) on d-TiO/FTO/glass substrate in MAI (50 mM), MABr (70 mM) in IPA solution at RT. FIG. 2B: Pb film (˜50 nm) reacted with FAI (100 mM) in IPA solutions at RT. FIG. 2C: glass-protected (left side in each frame) vs. Pb slide (right side) reaction with 100 mM MABr solution at RT after 1 h (left frame), 1 day (center frame) and 3 days (right frame). FIG. 2D: 120 nm Pb film on d-TiO₂/FTO/glass reacted with 50 mM MABr in IPA at ˜70° C. for 8 hours. FIG. 2E: (i) Pb film (˜100 nm) evaporated on d-TiO₂/FTO/glass substrate glass before and after treatment with MAI (50 mM for ˜2 hr) dissolved in IPA. (ii) Perovskite films after treatment of similar Pb films in solutions of (from left to right) 50 mM MAI, 70 mM MABr and 70 mM FABr for ˜2 hrs @ 20° C., 4 hrs @ 50° C. and 5 hrs @ 50° C., respectively. Verification for the structural identity of MAPbBr₃ and FAPbBr₃ can be found in FIGS. 3A and 3B. (iii) XRD patterns of a reacted Pb film (deposited on a glass substrate; ˜150 nm) with 50 mM MAI solution in IPA for (top) 1 hr (middle) 5 hr and (bottom) 28 hr. (iv) Plan-view SEM images of before (left) and after (right) immersing a Pb film deposited on glass in 50 mM MAI dissolved in IPA for 2 hr (since the Pb film is not densely packed, the reaction goes significantly faster).

FIG. 3A presents XRD patterns of MAPbI₃ and MAPbBr₃ films, of RT reaction of Pb films (50 nm on glass) reacted with 100 mM MABr solution in IPA for 24 hours and in 50 mM MAI in IPA for 110 minutes. In the latter, some elemental Pb is seen in the XRD pattern showing incomplete reaction. FIG. 3B shows XRD patterns of FAPbBr₃ obtained by dipping in 80 mM FABr solution of IPA a ˜100 nm of Pb deposited on FTO/d-TiO₂ substrate for 2 hours (first one hour was under electrical bias of 1V vs. Pt reference electrode (see Example 12 for more details).

FIGS. 4A-4E present SEM images of reacted Pb films (˜50 nm) on glass reacted in 25 mM MAI in IPA for 4 hours (FIG. 4A), 50 mM MAI (FIG. 4B), 100 mM MAI (FIG. 4C), 250 mM MAI (FIG. 4D), 500 mM MAI (FIG. 4E).

FIG. 5 presents SEM images of 120 nm Pb films treated with MABr solutions: 70 mM in IPA heated to ˜70° C.; cross section (left side); plan view (right side).

FIG. 6A presents 120 nm Pb films deposited on glass reacted with 46 mM MAI in IPA at room temperature containing different molar percentage of I₂ (relative to MAI). FIGS. 6B-6C: Plan-view SEM images of room-temperature reacted Pb films (˜100 nm) with 50 mM MAI salt with 10 mole % I₂ (relative to MAI) (FIG. 6B) and without I₂ (FIG. 6C) for 1 hour. Pb deposited on FTO.

FIG. 7A presents 120 nm Pb films deposited on glass reacted with 46 mM MABr in IPA at room temperature containing different molar percentages of Br₂ in (relative to MABr). FIG. 7B: Plan-view SEM images of room-temperature reacted Pb films (˜100 nm) with 50 mM MABr salt and 10 mole % Br₂ (relative to MABr) and without Br₂ (FIG. 7C) for 6 hours. Pb deposited on glass.

FIG. 8A presents plan-view SEM images of room-temperature reacted Pb film (˜100 nm) with 50 mM MAI salt and 10% HI or TFA acids (relative to MAI) for 1 hour. Pb deposited on FTO. FIG. 8B presents plan-view SEM images of room-temperature reacted Pb film (˜100 nm) with 50 mM MAI salt and 10% KOH base (relative to MAI) for 1 hour. Pb deposited on FTO.

FIG. 9 presents X-ray diffraction of a ˜100 nm Pb film on glass reacted in a solution of 80 mM CsBr in MeOH and containing ˜50 mM of HBr.

FIG. 10A presents optical transmission spectra (corrected for reflection) of Pb (˜100 nm) films reacted in 50 mM of MABr (in EtOH or IPA), MAI (in IPA) and MABr:MAI [1:1] molar ratio (in IPA). Based on the empirical equation E_{g}=1.57+0.39x+0.33x², the bandgap for the mixed perovskite corresponds to a Br:I ratio of ˜25:75. The spectra indicate that the coverage of MAPbI₃ is almost complete as % T_{corr} almost reaches zero at supra-bandgap wavelengths. The coverage of the other films is poorer, since light is being transmitted through uncovered areas (also demonstrated for MAPbBr₃ when comparing reaction in IPA or EtOH (FIG. 10C) The optical band gaps, calculated from these spectra, were 1.55, 1.68 and 2.26 eV for the MAPbI₃, MAPb(I,Br)₃ and MAPbBr₃ respectively. FIG. 10B presents SEM images of Pb film (˜100 nm on FTO) treated with 50 mM MAI for ˜2.5 hr in IPA (left) and an optical microscope image of the reacted film in EtOH (right). FIG. 10C presents SEM images of similarly reacted Pb films in 80 mM MABr in IPA (left) or EtOH (right) for 4 hr.

FIGS. 11A-11B present cross section back-scattered SEM images of MAPbI₃ cell made as described in Example 10 (FIG. 11A) and I-V curves of the cell in the dark and under I sun illumination (FIG. 11B).

FIGS. 12A-12B present a cross-sectional SEM image (FIG. 12A) of a MAPbBr₃ cell (compare with SEM image in Example 10 but without the hole conductor) and I-V curves of the cell in the dark and under I sun illumination (FIG. 12B).

FIG. 13 presents a picture of treatment of a (top) thermally-evaporated Sn film (˜100 nm) on glass with 0.5 M MAI in EtOH containing 0.5 M of HI and (bottom) Sn foil in a saturated (˜0.1 M) CsI solution dissolved in MeOH containing 0.5 M of HI.

FIG. 14 presents XRD patterns of the black coating after treating the Sn foil with the solution described in FIG. 13. XRD patterns are correlated with plane indices based on literature data. For MASnI₃, the diffraction pattern contains a large fraction of MAI (indicated with a star), some of the Sn substrate (indexed with circles) and the MASnI₃ perovskite (those which are indexed with crystallographic planes). For Cs₂SnI₆, Sn foil after immersing in CsI saturated methanol solution containing 0.5M of HI the pattern is clearly attributed to Cs₂SnI₆ (all the peaks are related to Cs₂SnI₆, as indexed with its crystallographic plane). The literature patterns of MASnI₃ and Cs₂SnI₆ are based on C. C. Stoumpos et al., Inorg. Chem. 52, 9019 (2013).

FIG. 15A presents reflection Vis-IR spectroscopy of reacted Sn foils in iodide salt solutions (as shown in FIG. 14). FIG. 15B presents Tauc plots based on the reflection spectra, in order to determine the optical band gap of the black coating. The results agree very well with values found in the literature for the optical bandgap of MASnI₃ (1.20 eV), FASnI₃ (1.41 eV) and Cs₂SnI₆ (1.26 eV) [based on C. C. Stoumpos et al., Inorg. Chem. 52, 9019 (2013) and B. Lee et al., J. Am. Chem Soc. 136, 15379, (2014)].

FIGS. 16A-16B present electrochemically-assisted conversion of Pb (˜100 nm on FTO) to MAPbI₃ (FIG. 16A) and MAPbBr₃ (FIG. 16B) in a solution of 50 mM MAI or 200 mM MABr in IPA. FIG. 16A(i) presents a photograph of the reaction system˜1 min after applying 0.75 V between the reference (R) and the working (W) electrodes. Both counter (C) and (R) electrodes are Pt coils. The working electrode is Pb on FTO/glass. The brown cloud next to the Pb electrode is electrochemically-generated polyiodide. FIG. 16A(ii) presents SEM images of plan (top) and cross-section (bottom) views of the electrochemically-assisted reacted films after 1 hr. FIG. 16A(iii) shows XRD diffraction patterns of electrochemically-assisted and non-electrochemically reacted films in 50 mM MAI/IPA. The disappearing Pb-{111} peak demonstrates the accelerated reaction rate. FIG. 16B(i) presents a photograph of the reaction system ˜1 min after applying 1.20 V between the reference (‘R’) and the working (‘W’) electrodes. Both counter (‘C’) and (R) electrodes are Pt coils. W is an evaporated film of Pb on FTO glass. The yellow cloud next to the Pb electrode is elemental, Br₂ which is yellow in IPA. FIG. 16B(ii) presents plan-view (top) and cross-section (bottom) SEM images of the electrochemically-assisted reacted films after 1 hr. FIG. 16B(iii) presents XRD diffraction pattern from reacted films under similar reaction conditions but with and without applying 1.20 V anodic bias to W. The Pb-{111} peak disappears after applying this bias for 1 r, indicating an accelerated reaction rate.

FIG. 17 presents (i) Cross-section SEM images of cells in which the halide perovskite is prepared in an electrochemically-assisted process (in both cases 1 V (vs. Ag/AgI) was applied to a FTO/d-TiO₂/Pb substrate against a Pt electrode for 20 min in 50 mM MAI (left) and 80 mM MABr (right) solutions in IPA). (ii) Dark and light (solar simulated 100 mW/cm²) I-V scans of MAPbI₃ and MAPbBr₃ cells where the perovskite was formed as in (i).

FIG. 18 presents a demonstration of control over Pb transformation (can be accelerated, slowed down or reversed) as a function of the applied electrical bias. Photographed samples of: (i) unreacted Pb film deposited on glass; (ii) reacted Pb films deposited on glass in 50 mM MAI in IPA for 5 min. (left) under ˜0.58 V bias vs. SHE and (right) disconnected from electrodes (potential in solution was measured to be ˜−0.25 V (iii) MAPbI₃ on FTO (obtained after transforming Pb) reacted in a similar solution as in (i) but under −1.08 V. All potentials were measured vs. Ag/AgI and then converted to the SHE scale.

FIGS. 19A-19C present time resolved photoluminescence spectroscopy of Pb films (on glass) treated with MAI and MABr in IPA. FIG. 19A: Pb films reacted with 50 mM MAI and 70 mM MABr. FIG. 19B: Pb films reacted with MABr at 70° C. with different additives. FIG. 19C: Pb films reacted with MAI at RT with different additives. Reaction times varied between the different reaction solutions.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In one embodiment, this invention is directed to a method for the preparation of halide perovskite or perovskite-related material. The main advantage of this invention is the reduced toxicity of the solution used in the process. Additionally, the metals (mainly Pb) are much less toxic in terms of manufacturing than the salts of the same metals. Further advantages are the preparation simplicity and a good morphology control of the perovskites prepared by the methods of this invention. This invention provides direct conversion of an elemental metal or alloy to a halide perovskite or perovskite related material.

In one embodiment, this invention provides a method for the preparation of halide perovskite or perovskite-related materials of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite related materials;
wherein the inorganic cation of A is different from the metal cation of B;
wherein said method comprises:
depositing a layer of metal or metal alloy of B on a substrate; and
   treating said layer of metal or metal alloy of B with a solution or vapor containing A and X wherein said solution or vapor reacts with said metal or metal alloy of B to form a halide perovskite or perovskite-related material of formula AᵤBᵥX_{w} on said solid surface;
   or
depositing a layer of a salt comprising A and X on a substrate; and
   treating said layer of salt with a vapor of metal or metal alloy of B; wherein said metal or metal alloy of B reacts with said salt to form a halide perovskite or perovskite-related material of formula AᵤBᵥX_{w} on said solid surface.

In another embodiment, the halide perovskite is of formula ABX₃ wherein:
A is any monovalent organic cation, inorganic cation or combination thereof.
B is at least one metal cation wherein, when combined with A and X, forms a halide perovskite material;
X is at least one halide anion, a pseudohalide anion or combination thereof.

A halide perovskite (not perovskite-related) refers to a material with a three-dimensional crystal structure related to that of CaTiO₃. The cubic ABX₃ perovskite structure consists of an extended three-dimensional (3-D) network of corner-sharing BX₆ octahedra, where B is generally a divalent metal and X a halide. The larger A cations fill the 12-fold coordinated holes among the octahedra. For the 3-D perovskites the size of the organic A cation is limited by the size of the 3-D hole into which it must fit. For a perfectly packed perovskite structure the geometrically imposed condition for the A, M, and X ions to be in close contact is (R_{A}+R_{X})=t√2 (R_{M}+R_{X}), where R_{A}, R_{M}, and R_{X} are the ionic radii for the corresponding ions and the tolerance factor must satisfy t≈1. Empirically, for most cubic or pseudo cubic perovskites, 1>t>0.8. The further t is from 1, the more distorted it is from a perfect cubic CaTiO₃ structure.

Lower-dimensional perovskites (defined herein as “perovskite-related”) are defined as structures that can conceptually be derived from specific cuts or slices of the 3-D perovskite structure. [Mitzi, D. B. in, Synthesis, Structure, and Properties of Organic-Inorganic Perovskites and Related Materials, Progress in Inorganic Chemistry, 1999, 1-121]. Their general formulas are:
For oriented families with a cut along the <100> direction:

A′₂Aₙ₋₁BₙX₃ₙ₊₁ or A′Aₙ₋₁BₙX₃ₙ₊₁; n is between 1-9
For oriented families with a cut along the <110> direction: A′₂AₘBₘX₃ₘ₊₂ or

A′AₘBₘX₃ₘ₊₂; m is between 1-9;
For oriented families with a cut along the <111> direction:

A′₂A_{q-1}B_{q}X_{3q+3} or A′A_{q-1}B_{q}X_{3q+3}; q is between 1-9;

wherein:
A is a monovalent organic cation or inorganic cation;
A′ is any monovalent or divalent organic cation;
wherein A and A′ are different;
X is at least one halide anion, a pseudohalide anion or combination thereof; and
B is at least one metal cation wherein, when combined with A and X, forms a halide perovskite-related material.

In another embodiment, a halide perovskite-related material refers to a material, represented by the following formula:

A′₂Aₙ₋₁BₙX₃ₙ₊₁ or A′Aₙ₋₁BₙX₃ₙ₊₁; n is between 1-9;

A′₂AₘBₘX₃ₘ₊₂ or A′AₘBₘX₃ₘ₊₂; m is between 1-9; or

A′₂A_{q-1}B_{q}X_{3q+1} or A′A_{q-1}B_{q}X_{3q+3}; q is between 1-9;

wherein:
A is a monovalent organic or inorganic cation;
A′ is any monovalent or divalent organic cation; wherein A and A′ are different.
X is at least one halide anion, a pseudohalide anion or combination thereof; and
B is at least one metal cation wherein, when combined with A and X, forms a halide perovskite-related material.

In one embodiment, this invention is directed to a method for the preparation of halide perovskite or perovskite-related material. In another embodiment A of the halide perovskite or perovskite related material prepared according to the methods of this invention is at least one monovalent or divalent organic cation, inorganic cation or combination thereof. In another embodiment, A is a monovalent organic cation. In another embodiment, A is a monovalent inorganic cation. In another embodiment, A is a divalent inorganic cation. In another embodiment, A is a divalent organic cation. In another embodiment, A is a large monovalent or divalent organic or inorganic cation. In another embodiment, A is a monovalent inorganic cation including Cs⁺. In another embodiment an “organic cation” refers to N(R)₄⁺, wherein R is the same or different hydrogen, unsubstituted or substituted C₁-C₂₀ alkyl, or unsubstituted or substituted aryl; the “organic cation” refers to C(R¹)₃⁺; wherein R¹ is the same or different hydrogen, unsubstituted or substituted C₁-C₂₀ alkyl, unsubstituted or substituted aryl or a primary, secondary or tertiary amine. In another embodiment A comprises an amine group, or ammonium group, wherein the amine or ammonium are primary, secondary, tertiary or quaternary groups. In another embodiment, A is CH₃NH₃⁺, CH(NH₂)₂⁺, alkylammonium, alkylamidinium, ammonium (NH₄⁺), EtNH₃⁺, PrNH₃⁺, BuNH₃⁺, t-BuNH₃⁺, formamidinium (FA⁺), iodoformamidinium, bromoformamidinium, Cs⁺, Rb⁺, Cu⁺.

In another embodiment, A includes more than one monovalent or divalent cation. The mixed-cation halide perovskite or perovskite-related material includes two, three or four different cations of A. Changes to the organic cation in the halide perovskite or perovskite related material has an impact on the structural and/or physical properties of the perovskite. By controlling the organic cation used, the electronic properties and the optical properties of the material may be controlled. For example, by changing the organic cation, the conductivity of the material may increase or decrease. Further, changing in organic cation may alter the band structure of the material this, for example, allowing control of the band gap for a semiconducting material.

In one embodiment, this invention is directed to a method for the preparation of halide perovskite-related material of formula A′₂Aₙ₋₁BₙX₃ₙ₊₁ or A′Aₙ₋₁BₙX₃ₙ₊₁; A′₂AₘBₘX₃ₘ₊₂ or A′AₘBₘX₃ₘ₊₂; or A′₂A_{q-1}B_{q}X_{3q+3} or A′A_{q-1}B_{q}X_{3q+3}. In another embodiment A′ is at least one monovalent or divalent organic cation, inorganic cation or combination thereof. In another embodiment, A′ is a monovalent organic cation. In another embodiment, A′ is a monovalent inorganic cation. In another embodiment, A′ is a divalent inorganic cation. In another embodiment, A′ is a divalent organic cation. In another embodiment, A′ is a large monovalent or divalent organic or inorganic cation. In another embodiment, A′ is a monovalent inorganic cation including Cs⁺. In another embodiment A′ comprises an amine group, or ammonium group, wherein the amine or ammonium are primary, secondary or tertiary groups. In another embodiment, A′ is a monovalent organic cation including CH₃NH₃⁺, CH(NH₂)₂⁺. In another embodiment an “organic cation” refers to N(R)₄⁺, wherein R is the same or different hydrogen, unsubstituted or substituted C₁-C₂₀ alkyl, or unsubstituted or substituted aryl; the “organic cation” refers to C(R¹)₃⁺; wherein R¹ is the same or different hydrogen, unsubstituted or substituted C₁-C₂₀ alkyl, unsubstituted or substituted aryl or a primary, secondary or tertiary amine. In another embodiment, A′ includes more than one monovalent or divalent cation. In another embodiment A′ comprises an amine group, or ammonium group, wherein the amine or ammonium are primary, secondary tertiary or quaternary groups. In another embodiment, A′ is CH₃NH₃⁺, CH(NH₂)₂⁺, ammonium (NH₄⁺), EtNH₃⁺, PrNH₃⁺, BuNH₃⁺, t-BuNH₃⁺, alkylamidinium, alkylammonium, formamidinium [FA⁺(CH(NH₂)₂⁺)], iodoformamidinium, bromoformamidinium, Cs⁺, Rb⁺, Cu⁺

As used herein an alkyl group can be a substituted or unsubstituted, linear or branched chain saturated radical. In another embodiment the alkyl chain, having from 1 to 20 carbon atoms. In another embodiment the alkyl chain, having from 1 to 10 carbon atoms. In another embodiment the alkyl chain, having from 1 to 5 carbon atoms. In another embodiment the alkyl chain, having from 2 to 10 carbon atoms. Non-limiting examples of an alkyl include: methyl, ethyl, propyl, butyl, pentyl, hexyl, heptyl, octyl, nonyl or decyl.

In another embodiment, the substituents of the alkyl group include one or more substituents selected from substituted or unsubstituted C₁-C₂₀ alkyl, substituted or unsubstituted aryl (as defined herein), cyano, amino, nitro, alkylamino, arylamino, amido, acylamido, hydroxy, oxo, halo, thio, carboxy, ester, acyl, acyloxy. C₁-C₂₀ alkoxy, aryloxy, or haloalkyl. In another embodiment, the substituted alkyl group includes between 1-3 substituents.

An aryl group is a substituted or unsubstituted, aromatic group which contains from 6 to 14 carbon atoms, preferably from 6 to 10 carbon atoms in the ring portion. Examples include phenyl, naphthyl, indenyl and indanyl groups.

An aryl group also refers to a heteroaryl group which is substituted or unsubstituted, monocyclic or bicyclic aromatic group which contains from 6 to 10 atoms in the ring portion including one or more heteroatoms selected from O, S, N, P, Se and Si. It may contain, for example, 1, 2 or 3 heteroatoms. Examples of heteroaryl groups include thiophenyl, pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

In another embodiment, the substituents of the aryl group include one or more substituents selected from substituted or unsubstituted C₁-C₂₀ alkyl, substituted or unsubstituted aryl (as defined herein), cyano, amino, nitro, alkylamino, arylamino, amido, acylamido, hydroxy, oxo, halo, thio, carboxy, ester, acyl, acyloxy, C₁-C₂₀alkoxy, aryloxy, or haloalkyl. In another embodiment, the substituted aryl group includes between 1-5 substituents.

In one embodiment, this invention is directed to a method of preparation of halide perovskite or perovskite-related material. In another embodiment B of the halide perovskite or perovskite-related material prepared according to the methods of this invention is at least one metal cation wherein, when combined with A and X, forms a halide perovskite or perovskite-related materials. In another embodiment, B is a metal cation with oxidation state of (2+). In another embodiment B is a metal cation of group (II) metals (Be, Mg, Ca, Sr, Ba) or group IV metals ((Ga, Sn, Pb), Eu, Zn Cd, Ni, Fe, Co, Cr, Pd, Pt). In another embodiment B is a mixture of metal cations comprising a mixture of one or more metals with oxidation state of (+2) with one or more metals having oxidation state of (+3) or (+1). Non-limiting examples of B alloys include a mixture of one or more metals of Group (II) metals [Be, Mg, Ca, Sr, Ba] or group (IV) metals [(Ga, Sn, Pb), Eu, Zn Cd, Ni, Fe, Co, Cr, Pd, Pt] with one or more metals of Group III metals [Bi, Tl, Sb, Ac, In, Ga, Al, P, Rh, Ru, Y, Sc, Lanthanides (Ce, La, Pr, Nd, Sm, Gd, Tb, Dy, Ho, Er, Tm, Yb, Lu), Ac, Au, Mn, Ag, Hg] or group (I) metals [Li, Na, K, Rb, Cs].

In another embodiment, B is Ca²⁺, Sr²⁺, Cd²⁺, Cu²⁺, Ni²⁺, Fe²⁺, Co²⁺, Pd²⁺, Ge²⁺, Bi²⁺, Sn²⁺, Pb²⁺, As²⁺, In²⁺, Ba²⁺, Mn²⁺, Yb²⁺, Eu²⁺ or combination thereof. In another embodiment, B is Pb²⁺. In another embodiment, B is Sn²⁺. In another embodiment, B is Ge²⁺. In another embodiment, B is Bi²⁺. In another embodiment, B is As²⁺. In another embodiment, B is In²⁺. In another embodiment, B is Ba²⁺. In another embodiment, B is Mn²⁺. In another embodiment, B is Sb²⁺. In another embodiment, B is Ca²⁺. In another embodiment, B is Sr²⁺. In another embodiment, B is Cd²⁺. In another embodiment, B is Cu²⁺. In another embodiment, B is Ni²⁺. In another embodiment, B is Fe²⁺. In another embodiment, B is Co²⁺. In another embodiment, B is Pd²⁺. In another embodiment, B is Yb²⁺. In another embodiment, B is Eu²⁺. In another embodiment, B includes more than one cation. The mixed-cation perovskite includes two, three or four different cations of B.

In another embodiment, B as described above is a metal cation or combination of metal cations. In another embodiment the methods of this invention comprises a step of “depositing a layer of metal or metal alloy of B” or “treating with a vapor of metal or metal alloy of B”. Such steps refer to the use of metal B or metal alloy of B as an elemental metal or an alloy. The elemental metal or alloy used in the methods of this invention correspond to the metal cation B obtained in the halide perovskites or perovskite-related materials. For example, using elemental metal or an alloy B for the deposition or treatment steps comprising Ca(0), Sr(0), Cd(0), Cu(0), Ni(0), Fe(0), Co(0), Pd(0), Ge(0), Bi(0), Sn(0), Pb(0), AS(0), In(0), Ba(0), Mn(0), Yb(0), Eu(0) or combination thereof.

In one embodiment, this invention is directed to a method of preparation of halide perovskite or perovskite-related material. In another embodiment X of the halide perovskite or perovskite-related material prepared according to the methods of this invention is at least one halide anion, a pseudohalide anion or combination thereof. The term “halide anion” refers to an anion of a group 7 element, i.e., of a halogen. In one embodiment, “halide anion” refers to a fluoride anion, a chloride anion, a bromide anion or an iodide anion. The term “a pseudohalide anion”, as used herein refers to an anion of polyatomic analogues of halogens. Non limiting examples of a pseudohalide anion include SeCN⁻, NCSe⁻, NCTe⁻, SCN⁻, CN—, NC⁻, OCN⁻, NCO⁻, NCS⁻, BH₄⁻, OSCN⁻, Co(CO)₄⁻, C(NO₂)₃⁻, C(CN)₃⁻) and N₃⁻. In another embodiment X is a bromide anion. In another embodiment X is an iodide anion. In another embodiment, X is a fluoride anion. In another embodiment X is a chloride anion. In another embodiment, X includes more than one anion. The mixed-anion perovskite includes two, three or four different anions of X.

In one embodiment, this invention is directed to a method of preparation of halide perovskite or perovskite-related material. In another embodiment u of the halide perovskite or perovskite-related material prepared according to the methods of this invention is an integer between 1 and 10. In another embodiment u is 1. In another embodiment u is 2. In another embodiment u is 3. In another embodiment u is between 2-10. In another embodiment v of the halide perovskite or perovskite-related material prepared according to the methods of this invention is an integer between 1 and 10. In another embodiment v is 1. In another embodiment v is 2. In another embodiment v is 3. In another embodiment v is between 2-10. In another embodiment w of the halide perovskite or perovskite-related material prepared according to the methods of this invention is an integer between 3 and 30. In another embodiment w is 3. In another embodiment w is 4. In another embodiment w is 5. In another embodiment w is 6. In another embodiment w is between 3 to 10.

In one embodiment, this invention is directed to a method of preparation of halide perovskite-related material In another embodiment n of the halide perovskite-related material prepared according to the methods of this invention is an integer between 1 and 9. In another embodiment n is 1. In another embodiment n is 2. In another embodiment n is 3. In another embodiment n is between 2 to 9. In another embodiment m of the halide perovskite-related material prepared according to the methods of this invention is an integer between 1 and 9. In another embodiment m is 1. In another embodiment m is 2. In another embodiment m is 3. In another embodiment m is between 2 to 9. In another embodiment q of the halide perovskite-related material prepared according to the methods of this invention is an integer between 1 and 9. In another embodiment q is 1. In another embodiment q is 2. In another embodiment q is 3. In another embodiment q is between 2 to 9.

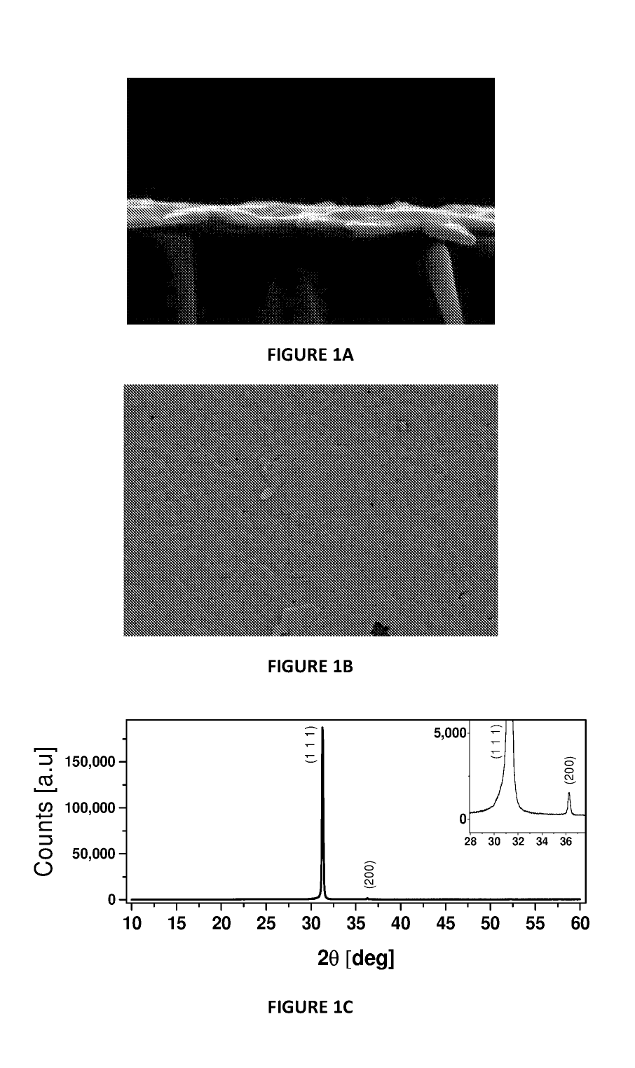

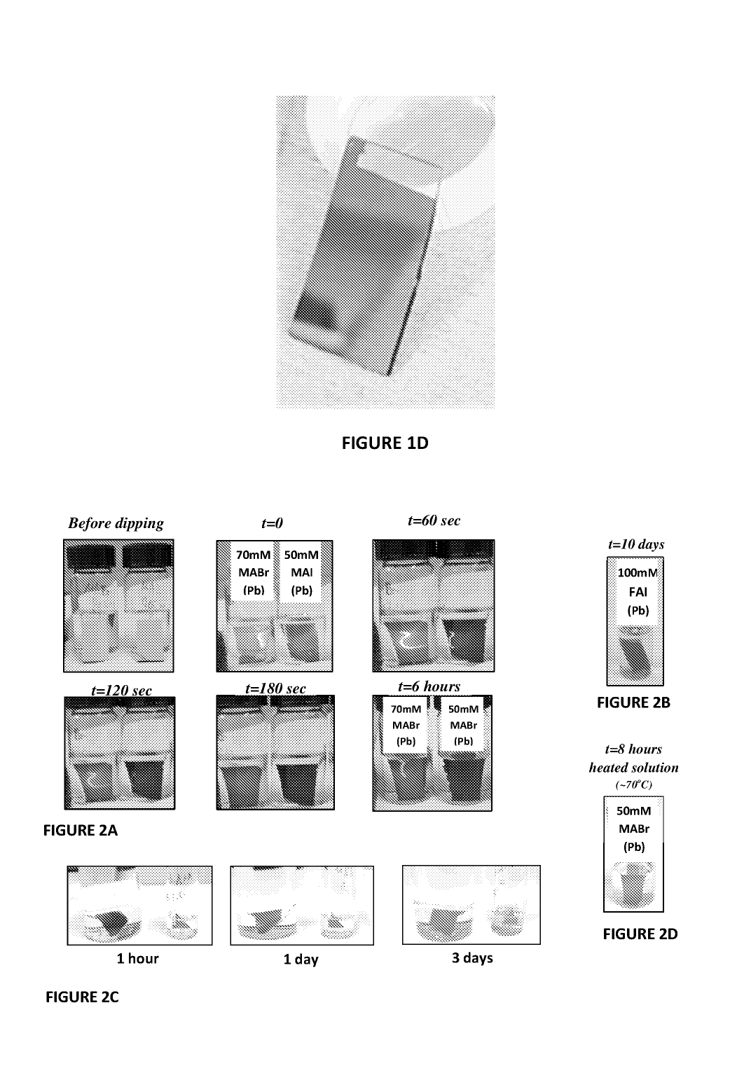

In one embodiment, this invention is directed to a method for the preparation of halide perovskite or perovskite-related material. In another embodiment, the method comprises depositing a layer of metal or metal alloy of B on a substrate. In another embodiment, the metal or metal alloy of B (elemental metal, not the cationic form of B) is deposited on the substrate. In another embodiment, depositing the layer of metal or metal alloy of B on a substrate is performed by any method known in the art. In another embodiment, metal or metal alloy of B is deposited on the substrate by evaporation. In another embodiment, metal or metal alloy of B is deposited on the substrate by electrodeposition. In another embodiment, the metal or metal alloy of B is deposited on the substrate by electroless plating. In another embodiment, the thickness of the metal or metal alloy of B layer on the substrate depends on the use of the perovskite prepared by the methods of this invention. For example, for photovoltaic applications, the thickness is approximately the light absorption depth of the perovskite, often a few hundred nm. For optoelectronic devices, the thickness may vary between an ultra-thin layer (a few nm) and at least several μm. In another embodiment, for these applications, the thickness is between 1-1000 nm. In another embodiment, the thickness is between 1-100 nm. In another embodiment, the thickness is between 1-10 nm. In another embodiment, the thickness is between 1-5 μm. In one embodiment, if a full conversion to a halide perovskite or perovskite-related material occurs, the thickness of the converted metallic B will be determined by the overall thickness of the deposited metal or metal alloy. In one embodiment, FIGS. 1A-ID present deposited Pb on a glass microscope slide.

In one embodiment, the method of this invention includes a step of treating the layer of metal or metal alloy of B with a solution or vapor comprising A and X wherein said solution or vapor reacts with said metal or metal alloy of B to form a halide perovskite or perovskite-related material of formula AᵤBᵥX_{w} on a solid surface. In another embodiment, the solution or vapor comprising A and X include: ammonium and halide, organic cation comprising an amine and halide, formamidinium and halide, ammonium and pseudohalide, formamidinium and pseudohalide, organic cation comprising an amine and pseudohalide, a monovalent metal cation and halide, monovalent metal cation and pseudohalide; divalent metal cation and halide, divalent metal cation and pseudohalide or combination thereof. Non limiting examples include: CH₃NH₃I (=methylammonium iodide, MAI), CH₃NH₃Br (=methylammonium bromide, MABr), CH(NH₂)₂I (formamidinium iodide, FAI) CH(NH₂)₂Br (formamidinium bromide, FABr), C(I)(NH₂)₂I (iodoformamidinium iodide), CsI, CsBr, RbI and RbBr.

The solvent used for the solution, comprising A and X is any solvent in which the solubility of the materials comprising A, A′ and X is much higher than the solubility of the product (halide perovskite or perovskite-related material) or the solubility of metal or metal alloy B. In another embodiment, the solvent is a polar solvent. In another embodiment, the solvent is an alcohol acetonitrile, a solvent with a nitro group, a solvent with a carboxylic group, a solvent with a cyano group. In another embodiment, the solvent is methanol acetonitrile, isopropanol, ethanol butanol or a combination thereof. In another embodiment, as the chain length of the alcohol increases, the reaction rate decreases.

In another embodiment, the concentration of A and X in the solution is between 0.1 mM and 3M.

In one embodiment, the treating step of the film layer of metal or metal alloy of B with a solution or vapor comprising A and X includes the optional addition of external additive comprising a halogen (F₂, Cl₂, Br₂, I₂), HI, HCl, HBr, HF, HCN, S(CN)₂, haloalkane, haloarene, haloheteroarene, halocycloalkane, reducing agents, halogen salts or combination thereof. In one embodiment, haloalkane refers to an alkyl group as defined above, which is substituted by one or more halogen atoms, e.g. by F, Cl, Br or I. Nonlimiting examples of haloalkyl groups are CF₃, CF₂CF₃, CH₂CF₃.

In one embodiment haloarene refers to an aryl group as defined above, which is substituted by one or more halogen atoms, e.g. by F, Cl, Br or I. Nonlimiting examples of haloarene groups are bromophenyl, chlorophenyl, 1,4 dichlorophenyl, iodophenyl, 1,4 dioodophenyl.

In one embodiment haloheteroarene refers to a heteroaryl group which is substituted by one or more halogen atoms, e.g. by F, Cl, Br or I. A heteroaryl group refers to an aryl as defined above, wherein one or more of the carbon atoms are replaced by sulfur, oxygen, nitrogen or any combination thereof. Nonlimiting examples of haloheteroarene are chloropyridine, iodopyridine, bromopyridine, bromoindole, iodoindole, fluoroquinoline, iodoquinoline, bromoquinoline.

In one embodiment halocycloalkane refers to a heterocycloalkyl group which is substituted by one or more halogen atoms, e.g. by F, Cl, Br or I. A heterocycloalkyl group refers to a saturated ring structure comprising in addition to carbon atoms, sulfur, oxygen, nitrogen or any combination thereof, as part of the ring. In another embodiment the heterocycloalkyl is a 3-12-membered ring. In another embodiment the heterocycloalkyl is a 6-membered ring. Non-limiting examples of halocycloalkane are chloropiperidine, iodopiperidine, bromopiperidine, bromopyrrole, iodomorpholine, fluoromorpholine, bromomorpholine.

In one embodiment a reducing agent refers to a reagent, which can stabilize metals at a required oxidation state, for example, preventing oxidized Sn²⁺ to oxidize further to Sn⁺⁴. Non-limiting examples of reducing agents are NaBH₄ or H₃PO₂.

In one embodiment halogen salts comprise a halogen salt of the metal or metal alloy B, where SnF₂ or PbF₂ are examples of these.

In another embodiment, the concentration of the external additive in the solution is between 0.05% to 25% (molar %; relative to the salt).

In one embodiment, the method of this invention comprises a treating step of the metal or alloy of B layer with a solution or vapor comprising A and X. In another embodiment, the treatment step is carried out at room temperature. In another embodiment, the treatment step is carried out at a temperature between 10-150 deg° C. In another embodiment, the temperature is between 15-80 deg C. In another embodiment, the temperature is between 20-100 deg° C.

Examples 1-8 provide embodiments for the methods of this invention.

In one embodiment, the method of this invention for the preparation of halide perovskite or related perovskite comprises a treating step of the metal or alloy of B layer with a solution or vapor comprising A and X. In another embodiment, the method for the preparation of halide perovskite or related perovskite can be controlled by applying electrical bias on the different layers; for example, by anodic oxidation of the metal and/or oxidation of X⁻ at the metal or metal alloy surface this reaction can be accelerated. In another embodiment, a positive bias is applied to said deposited layer of metal or metal alloy of B in an alcoholic solution. In another embodiment, the electrochemical (anodic) reaction is carried out at positive bias, preferentially for MAX, between +0.25 V and +1.0 V. The electrolysis can also be carried out under non DC conditions (e.g. pulsed current), and in this case the potentials may be very different. In another embodiment, the process is reversible.

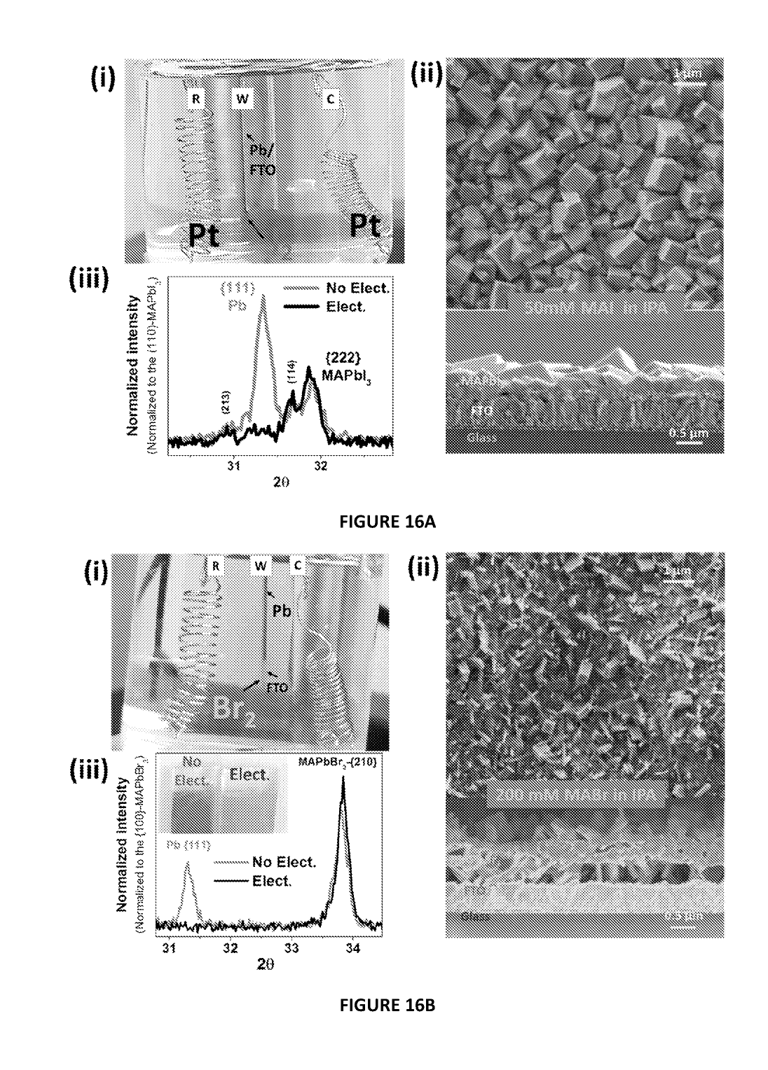

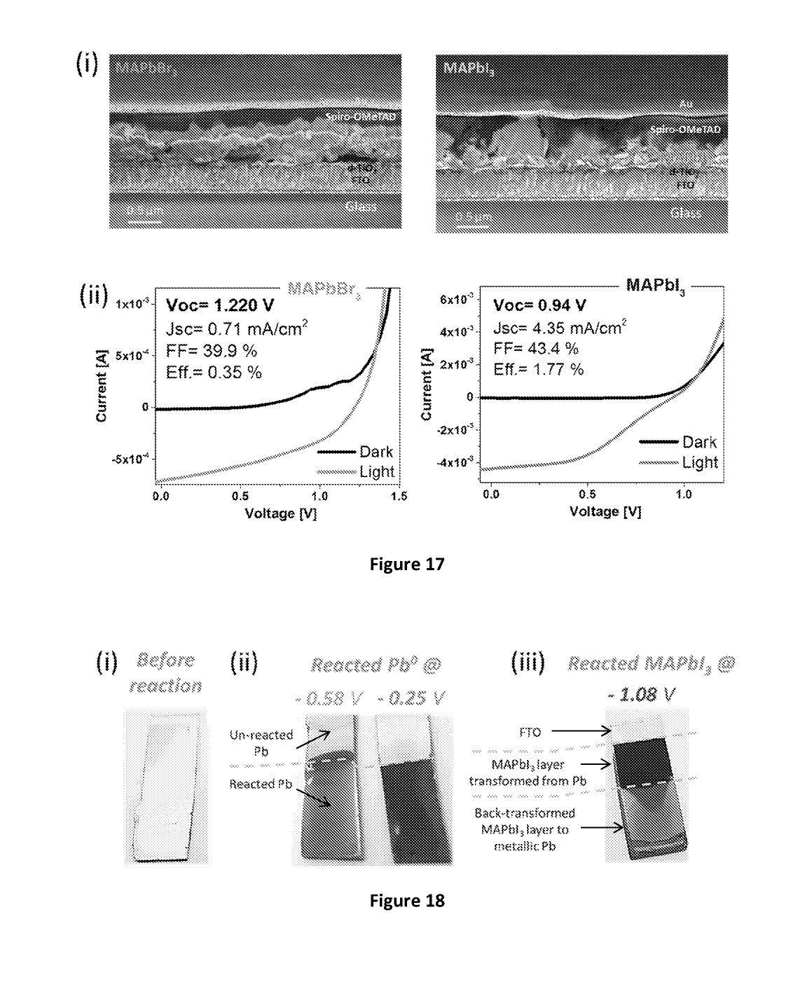

In another embodiment, the electrochemical reaction is described in Example 12 and FIGS. 16A-16B.

In one embodiment, this invention is directed to a method for the preparation of halide perovskite or perovskite-related material. In another embodiment, the method comprises depositing a layer of a salt comprising A and X on a substrate.

In another embodiment, depositing the layer of the salt on a substrate is performed by any method known in the art. In another embodiment, the salt is deposited on the substrate by evaporation or solution methods (spin-coating, spray, screen printing).

In another embodiment, the thickness of the layer of the salt on the substrate depends on the use of the perovskite prepared by the methods of this invention. For example, for photovoltaic applications, the thickness is approximately the light absorption depth of the halide perovskite or perovskite-related material often a few hundred nm. For optoelectronic devices, the thickness may vary between an ultra-thin layer (a few nm) and at least several μm. For these applications, in another embodiment, the thickness is between 1-1000 nm. In another embodiment, the thickness is between 1-100 nm. In another embodiment, the thickness is between 1-10 nm. In another embodiment, the thickness is between 1-5 μm. In one embodiment, if a full conversion to a halide perovskite or perovskite-related material occurs, the thickness of the salt layer will be determined by the overall thickness of the deposited metal or metal alloy.

In another embodiment, the salt comprising A and X includes: alkylammonium halide, ammonium halide organic cation including an amine and halide; formamidinium halide; alkylammonium pseudohalide, ammonium halide, formamidinium pseudohalide, a monovalent metal cation—halide, monovalent metal cation—pseudohalide; divalent metal cation—halide, divalent metal cation—pseudohalide, alkylamidinium-halide, alkylamidinium—pseudohalide, or combination thereof. Non limiting examples include: CH₃NH₃I (=methylammonium iodide, MAI), CH₃NH₃Br (=methylammonium bromide, MABr), CH(NH₂)₂I (formamidinium iodide, FAI), CH(NH₂)₂Br (formamidinium bromide, FABr), C(I)(NH₂)₂I (iodoformamidinium iodide), CsI, CsBr, RbI and RbBr. In one embodiment, the method of this invention includes a step of treating the layer of the salt with vapor of metal or metal alloy of B; wherein said metal or metal alloy of B reacts with said salt to form a halide perovskite or perovskite-related material of formula AᵤBᵥX_{w} on said solid surface.

In one embodiment, the method of this invention comprises a step of depositing a layer of metal or metal alloy of B on a substrate or depositing a layer of a salt comprising A and X on a substrate. In another embodiment, the layer is a continuous or non continuous film, quantum dots, a porous layer, etc.

In one embodiment, the method of this invention comprises a step of depositing a layer of metal or metal alloy of B on a substrate or depositing a layer of a salt comprising A and X on a substrate. In another embodiment, the substrate is any substrate. In another embodiment, the substrate is a planar substrate. In another embodiment, the substrate is a carbon-based one, GaAs, ceramic materials containing ions from groups III and V; ceramic materials containing ions from groups II-VI, glass, conducting glass, coated glass, metal film or sheet, nano- or meso-porous substrate, mesoporous oxides, d-TiO₂/FTO (Fluorine-doped Tin Oxide), ITO, (100) p-type (boron doped) Si, n-type (phosphorous-doped) Si, dense TiO₂ on top of fluorine-doped tin oxide (FTO)-coated glass (d-TiO₂) or combination thereof. In another embodiment, the substrate is a glass. In another embodiment, the substrate is a conducting glass. In another embodiment, the substrate is a glass, coated by a conducting material. In another embodiment, the substrate is a carbon-based substrate. In another embodiment, the substrate is GaAs. In another embodiment, the substrate is a ceramic material containing ions from groups III and V. In another embodiment, the substrate is a ceramic material containing ions from groups II-VI. In another embodiment, the substrate is a metal sheet. In another embodiment, the substrate is a metal film. In another embodiment, the substrate is a nano/mesoporous substrate. In another embodiment, the substrate is a nanoparticle. In another embodiment, the substrate is a mesoporous oxide. In another embodiment, the substrate is a nanoporous material. In another embodiment, the substrate is a fluorine-doped tin oxide (FTO) coated glass. In another embodiment, the substrate is Fluorine-doped tin oxide (FTO) coated glass. In another embodiment, the substrate is p-type (boron-doped) Si In another embodiment, the substrate is undoped p-type—Si In another embodiment, the substrate is a d-TiO₂/FTO coated glass. In another embodiment, the substrate is glass, conducting glass, coated glass, metal film or sheet, nano or meso porous substrate, mesoporous oxides, d-TiO₂/FTO (Fluorine-TinOxide), (100) p-type (boron doped) Si, dense TiO₂ on top of fluorine-doped tin oxide (FTO)-coated glass (d-TiO₂) or combination thereof.

The term “mesoporous”, as used herein, means that the pores in the porous layer are microscopic and have a size, which is usefully measured in nanometres (nm). The mean pore size of the pores within a “mesoporous” structure may for instance be anywhere in the range of from 1 nm to 100 nm, or for instance from 2 nm to 50 nm. Individual pores may be different sizes and may be any shape. In one embodiment, the porous layer of a semiconductor comprises TiO₂. More generally, the porous layer comprises mesoporous oxides.

In another embodiment, the substrate is any material that is stable to the processing steps and allows good quality deposition of the initial deposition.

In one embodiment, the initial deposit (of a metal/metal alloy of B or of the salt comprising A and X) is patterned onto a substrate (including Si) using well-established up-scalable technologies (e.g. VLSI processing, shadow-mask metal evaporation, electroplating or electroless plating onto, monolayer-treated substrates, etc).

The thickness of the resulting halide perovskite or perovskite-related material is determined by the thickness of the initial metal/alloy or salt deposit. The composition can be controlled both by the composition of the initial deposit and by the composition of the treatment step.

The morphology of the halide perovskite or perovskite-related material is very important in determining the properties of the device/cell. The desired morphology depends on the intended use of the halide perovskite or perovskite-related material. The salt concentration, temperature of the solution treatment, and the nature of the solvent and additives added to the salt solution affect the morphology and properties of the device/cell.

In one embodiment, the halide perovskite or perovskite-related material prepared according to the methods of this invention is MAPbI₃, MAPbBr₃, MAPb(Br,I)₃, FAPbI₃, FAPbBr₃, FAPb(Br,I)₃, CsPbI₃, CsPbBr₃ or CsPb(Br,I)₃, (Cs,FA)PbI₃, MA(Pb,Sn)I₃.

### Applications

In one embodiment, the present invention provides an optoelectronic device comprising a halide perovskite or perovskite-related material prepared according to the methods of this invention.

In one embodiment, the present invention provides a photovoltaic cell comprising a halide perovskite or perovskite-related material prepared according to the methods of this invention.

The halide perovskite and perovskite-related material prepared according to the methods of this invention are used in solar cell production. In one embodiment single junction solar cells comprise the halide perovskite or perovskite-related material prepared according to the methods of this invention. In one embodiment, a high photon energy cell to complement other presently manufactured (e.g. Si) solar cells comprises the halide perovskite or perovskite-related material prepared according to the method of this invention.

In one embodiment, this invention is directed to an optoelectronic device comprising a halide perovskite or perovskite-related material of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite-related materials;
wherein the inorganic cation of A is different from the metal cation of B;
wherein said halide perovskite or perovskite-related material of formula AᵤBᵥX_{w} is prepared according to the methods of this invention.

In one embodiment, this invention provides a photovoltaic cell comprising a halide perovskite or perovskite-related material of formula AᵤBᵥX_{w};

wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite-related materials;
wherein the inorganic cation of A is different from the metal cation of B;
wherein said halide perovskite or perovskite-related material of formula AᵤBᵥX_{w} is prepared according to the methods of this invention.

In one embodiment, the optoelectronic device or the photovoltaic cell of the invention comprise a first electrode; a second electrode; and disposed between the first and second electrodes a thin layer comprising a perovskite prepared according to the methods of this invention. In one embodiment, the optoelectronic device of this invention comprises a first electrode and a second electrode, which are an anode and a cathode, one or both of which is transparent to allow the entering of light.

The choice of the first and second electrodes of the optoelectronic devices/photovoltaic cell of the present invention may depend on the structure type. Typically, the n-type layer is deposited onto a transparent conductive oxide (TCO), such as tin oxide, more typically onto a fluorine-doped tin oxide (FTO) anode, or indium tin oxide (ITO) which is usually a transparent or semi-transparent material. Thus, the first electrode is usually transparent or semi-transparent and typically comprises FTO or ITO. Usually, the thickness of the first electrode is from 200 nm to 1 μm, preferably, from 200 nm to 600 nm, more preferably from 300 to 500 nm. For instance the thickness may be 400 nm. Typically, FTO is coated onto a glass sheet. In one embodiment, (when an electrode is addressed to collect ‘holes’ (i.e. positive charges)), the second electrode comprises a high work function metal, for instance gold, silver, nickel, palladium or platinum, and typically silver. In another embodiment, carbon (in any form, e.g. graphite, graphene, carbon paste or fullerenes) may also be used as a second electrode. In one embodiment, the thickness of the second electrode is from 50 nm to 250 nm, preferably from 100 nm to 200 nm. For instance, the thickness of the second electrode may be 150 nm.

As used herein, the term “thickness” refers to the average thickness of a component of an optoelectronic device.

In one embodiment, the optoelectronic device or photovoltaic cell of the invention comprises: a first electrode; a second electrode; and disposed between the first and second electrodes: (i) a layer of a semiconductor; and (ii) a perovskite prepared according to the methods of this invention.

The term “semiconductor” as used herein refers to a material with electrical conductivity intermediate in magnitude between that of a conductor and an insulator. The semiconductor may be an intrinsic semiconductor, an n-type semiconductor or a p-type semiconductor. Examples of semiconductors include halide perovskite or perovskite-related material; oxides of titanium, niobium, tin, zinc, cadmium, copper or lead; chalcogenides of antimony, copper, zinc, iron, or bismuth (e.g. copper sulphide and iron sulphide); copper zinc tin chalcogenides, for example, copper zinc tin sulphides such a Cu₂ZnSnS₄ (CZTS) and copper zinc tin sulphur-selenides such as Cu₂ZnSn(S₁₋ₓSeₓ)₄ (CZTSSe); copper indium chalcogenides such as copper indium selenide (CIS); copper indium gallium chalcogenides such as copper indium gallium selenides (CuIni₋ₓGaₓSe₂) (CIGS); or copper indium gallium diselenide. Further examples are group IV semiconductors and compound semiconductors (e.g. silicon, germanium, silicon carbide); group III-V semiconductors (e.g. gallium arsenide); group II-VI semiconductors (e.g. cadmium selenide); group I-VII semiconductors (e.g. cuprous chloride); group IV-VI semiconductors (e.g. lead selenide); group V-VI semiconductors (e.g. bismuth telluride); and group II-V semiconductors (e.g. cadmium arsenide); ternary or quaternary semiconductors (eg. Copper Indium Selenide, Copper indium gallium di-selenide, copper zinc tin sulphide, or copper zinc tin sulphide selenide (CZTSSe).

In one embodiment, the phovoltaic cell comprises a hole conductor. In another embodiment, the hole conductor is spiro-OMeTAD ((2,2′,7,7′-tetrakis-(N,N-di-p-methoxyphenylamine)9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopenta[2,1-b:3,4-b′]dithiophene-2,6-diyl]]), PV (poly(N-vinylcarbazole)), HTM-TFSI (1-hexyl-3-methylimidazolium bis(trifluoromethylsulfonyl)imide), Li-TFSI (lithium bis(trifluoromethanesulfonyl)imide) or tBP (tert-butylpyridine). In another embodiment, the hole conductor is inorganic hole conductors such as NiO, CuSCN or Cu₂O.

In another embodiment, the photovoltaic cell comprises the following layers: glass/FTO/d-TiO₂/halide perovskite or perovskite-related/spiro-OMeTAD/AU. In another embodiment, the photovoltaic cell comprises the following layers: glass/FTO/d-TiO₂/halide perovskite or perovskite-related/Au.

In one embodiment, the optoelectronic device is a photo-transistor. In one embodiment, the optoelectronic device is a photo-diode, including a light-emitting diode. In one embodiment, the optoelectronic device is a photo-resistor. In one embodiment, the optoelectronic device is a photo-detector.

In one embodiment, the optoelectronic device of this invention is photo induced high-voltage electrical power source for water-splitting for H₂ production. In one embodiment, the optoelectronic device of this invention is photo-induced high-voltage electrical power source for CO₂ reduction for fuel production. In one embodiment, the optoelectronic device of this invention is photo-induced high-voltage electrical power source for chemical redox reactions that will be powered by light.

In one embodiment, the device/cell of this invention comprises more than one halide perovskite or perovskite related layer wherein each perovskite may be prepared by the method of this invention. In another embodiment, the optoelectronic device/photovoltaic cell comprises two or three different perovskites.

### Abbreviations

d-TiO₂: dense titanium oxide
FA: formamidinium, CH(NH₂)₂
FABr: formamidinium bromide, CH(NH₂)₂Br
FAI: formamidinium iodide, CH(NH₂)₂I
FTO: fluorine-doped tin oxide
IPA: isopropanol
MA: methyl ammonium, CH₃NH₃⁺
MABr: methylammonium bromide, CH₃NH₃Br
MAI: methylammonium iodide, CH₃NH₃I
RT: room temperature
SEM: scanning electron microscopy
TCO: transparent conductive oxide

The following examples are presented in order to more fully illustrate the preferred embodiments of the invention. They should in no way be construed, however, as limiting the broad scope of the invention.

### EXAMPLES

### Example 1

### Conversion of Metallic Lead (Pb) to MAPbX₃

Thermal evaporation of Pb was carried out on three different substrates.
Glass microscope slide
Dense-TiO₂ on top of fluorine-doped tin oxide (FTO)-coated glass (d-TiO₂).
(100) p-type (boron doped) Si

In all three cases a shiny layer of Pb metal with controlled thickness was obtained. Powder X-ray diffraction (XRD) and scanning electron microscope (SEM) images (

FIGS. 1A-D) and concentration optimization to roughly optimize morphology were done with ˜50 or ˜120 nm thick evaporated Pb.

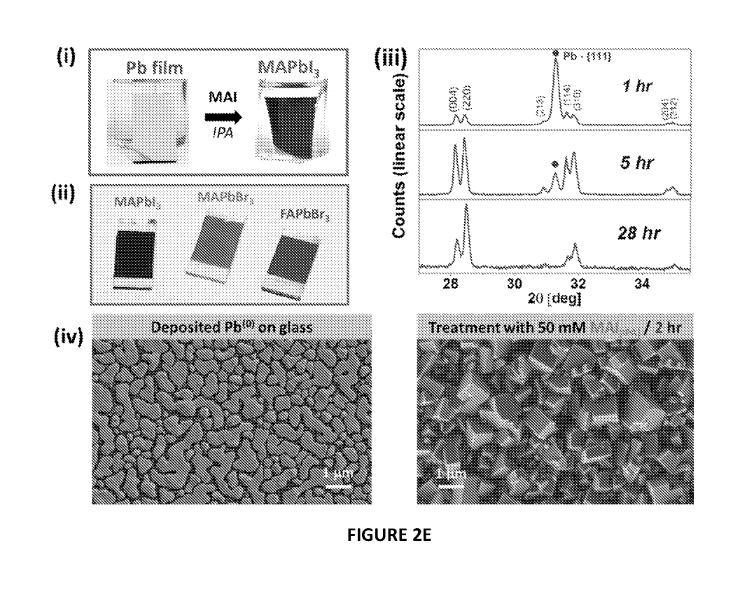

The evaporated Pb layers were placed in vials filled with various alcoholic solutions of 0.05-0.1M methylammonium iodide (MAI), methylammonium bromide (MABr) and formamidinium iodide (FAI). Methanolic solutions of MAI reacted extremely rapidly and essentially etched the layers from the substrate. Ethanolic MAI converted the shiny silver-gray Pb layer to a black coating. The reaction at room temperature began immediately. However, complete conversion of the film required much longer (several hours). FIG. 2E(i) shows this conversion (using 50 mM MAI). FIG. 2E(iii) shows the XRD pattern of a partially converted film with the metal Pb peak at ˜31 degrees acting as a qualitative guide to the degree of conversion.

The rate of conversion is dependent on the halide ion. The reaction with MABr to MAPbBr₃ is slower than that with MAI to MAPbI₃ and requires either a higher concentration of MABr and/or a higher temperature (FIG. 2E(ii)—center) than is the case for the iodide. A Pb film was reacted with 70 mM MABr for 4 h at 50° C. and completely transformed into MAPbBr₃. The same is true for FAPbBr₃ (FIG. 2E(h)—right). There was not a large difference in reaction rate between the FA and MA, albeit that the MA rate was a little lower). During the FAI reaction it was easy to identify the complete transformation, since unreacted Pb in the orange MA- (or FA)PbBr₃ gave a visually grey coloration, in contrast to complete conversion (FIG. 2E(iii)). A ˜50 nm Pb film layer, was reacted with MAI/IPA for ˜2-3 hours and completely transformed into black film of MAPbI₃ and about a day was required to convert with MABr/IPA (orange film of MAPbBr₃) and FAI/IPA (yellow &-FAPbI₃) followed by a brown-colored film layer.

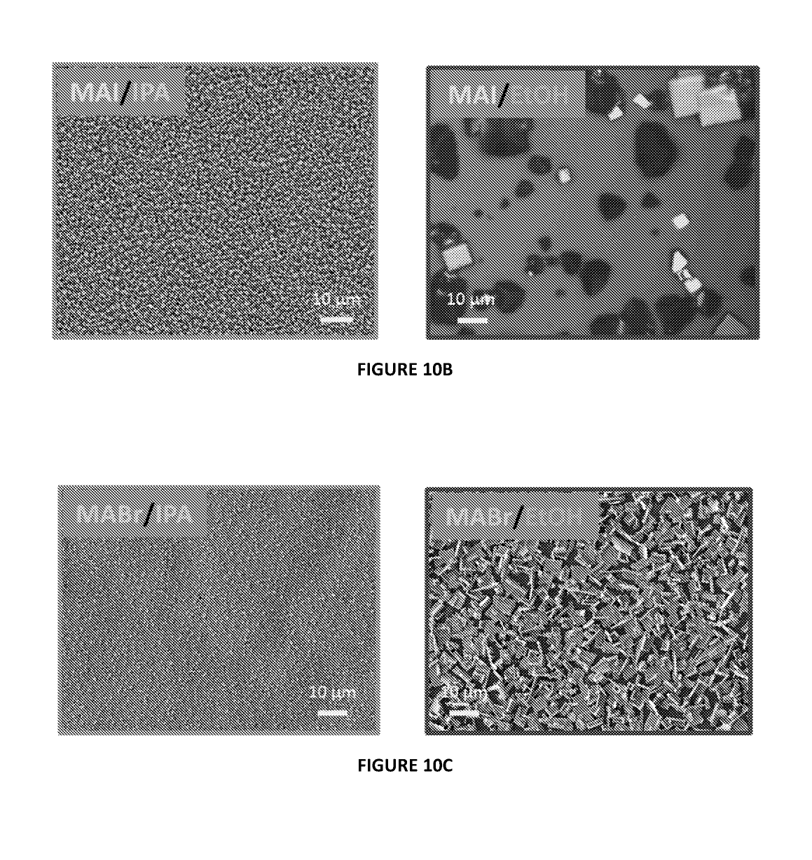

The nature of the alcohol affected both the conversion rate and film morphology (FIG. 10B); the lower the molecular weight of the alcohol, the more rapid the conversion. The reaction with EtOH compared with IPA, was faster, but the film quality was poorer, the reaction with IPA was more controlled. For the case of MeOH, the metallic film was completely dissolved into the solution. The reaction with isopropanol (IPA) was slower compared with butanol.

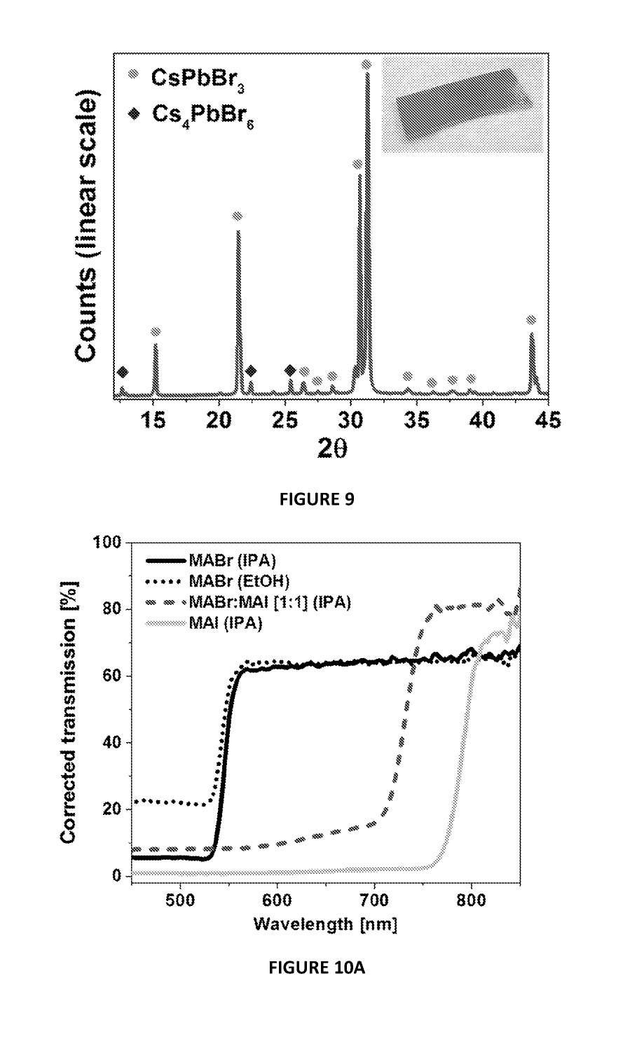

When changing the organic cation to an inorganic cation, i.e. Cs, IPA is no longer a suitable solvent for the Pb transformation reaction, due to the poor solubility of CsX salts in IPA. Therefore, MeOH, in which the solubility of CsBr is reasonably high (and can increase with the presence of an acid (e,g, HBr)) (FIG. 9), is a more suitable solvent whenever using a fully inorganic AX salt.

Other factors that affect the conversion rate are:

Porosity of the Pb layer. A more porous, less dense Pb layer reacted more rapidly. Since the volume expansion of the Pb conversion to perovskite is ˜×3, a dense perovskite layer was formed from a porous Pb layer (FIG. 2E(iv)).

Addition of add (HI, HBr, TFA (trifluoroacetic acid)) increased the rate somewhat but usually not to a major extent.

Addition of free bromine or iodine increased the conversion rate somewhat, at least initially, based on visual observation. The free halogen is normally present in small extent in the HI solution (as in water) as seen from the yellowish coloration of this acid, and this coloration increases with storage time and exposure to air and light.

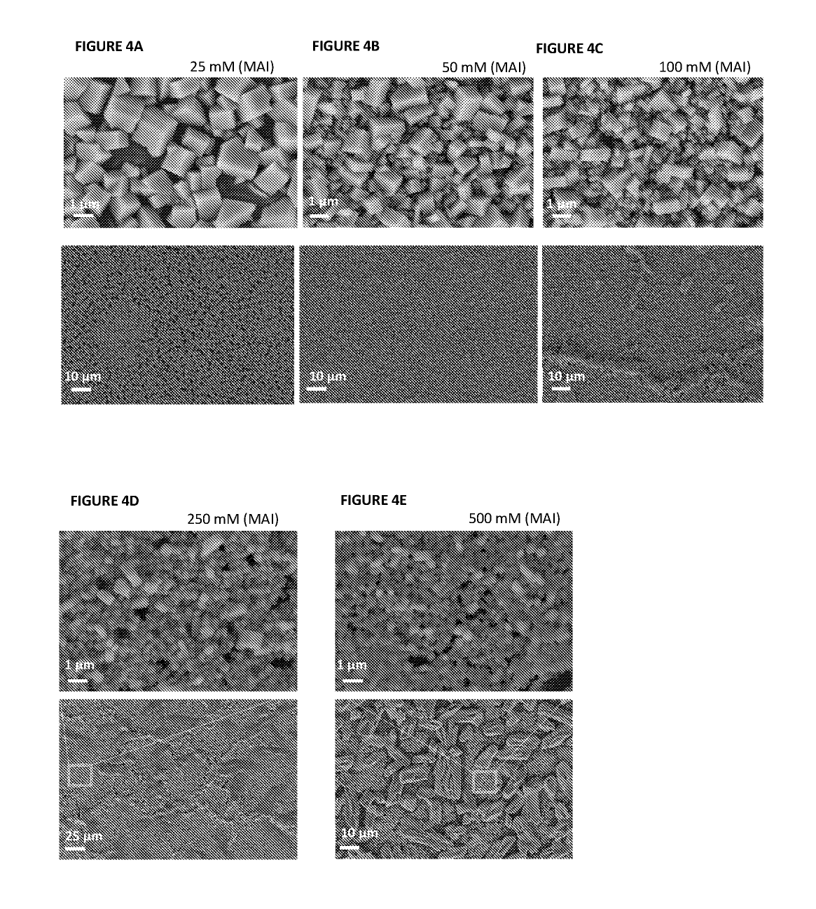

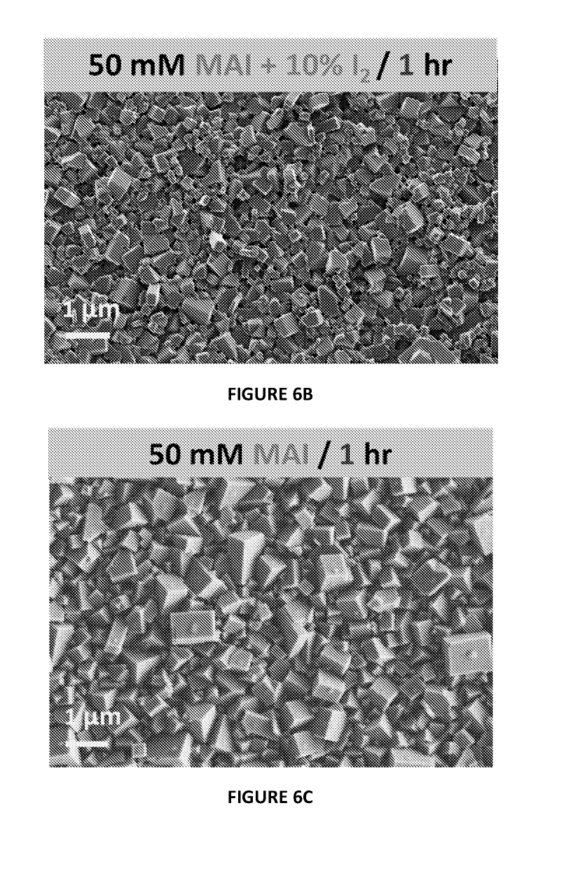

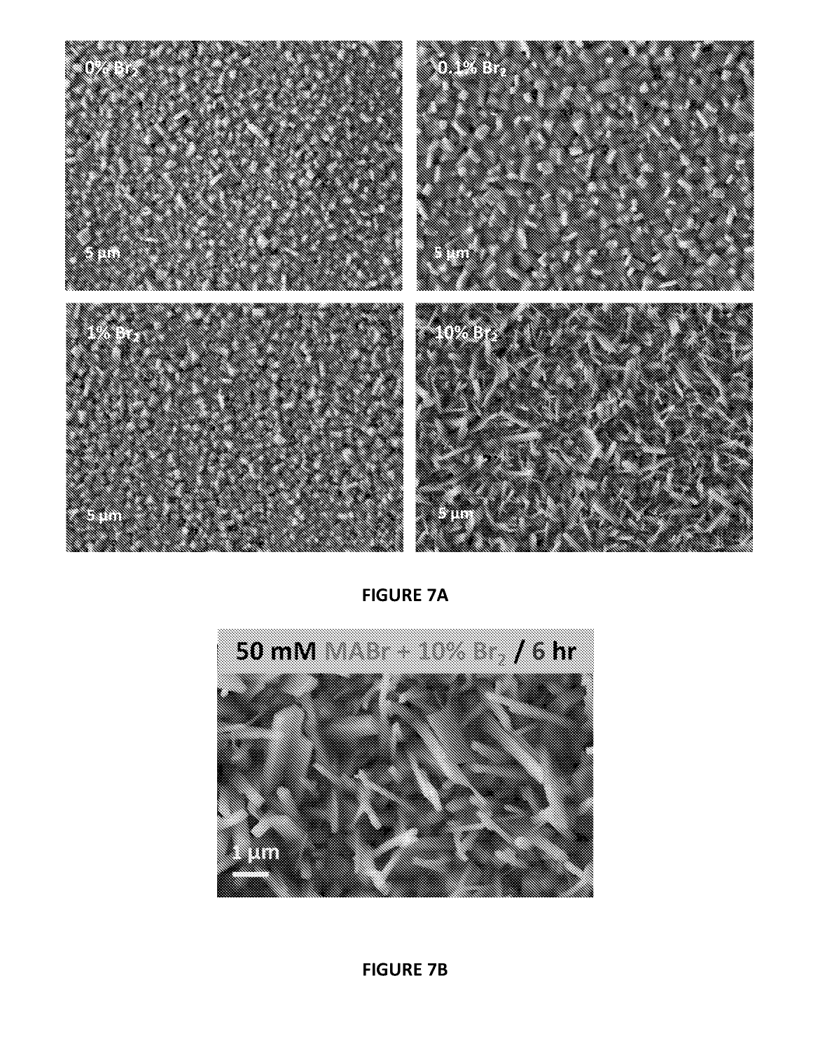

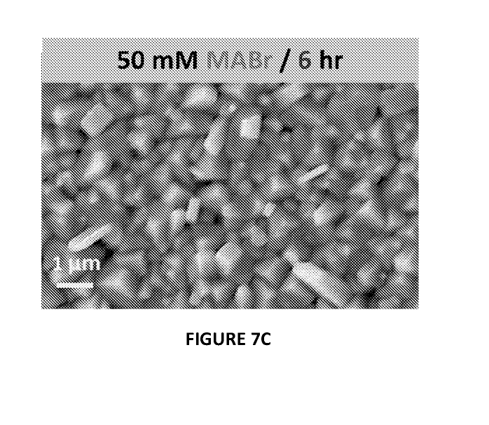

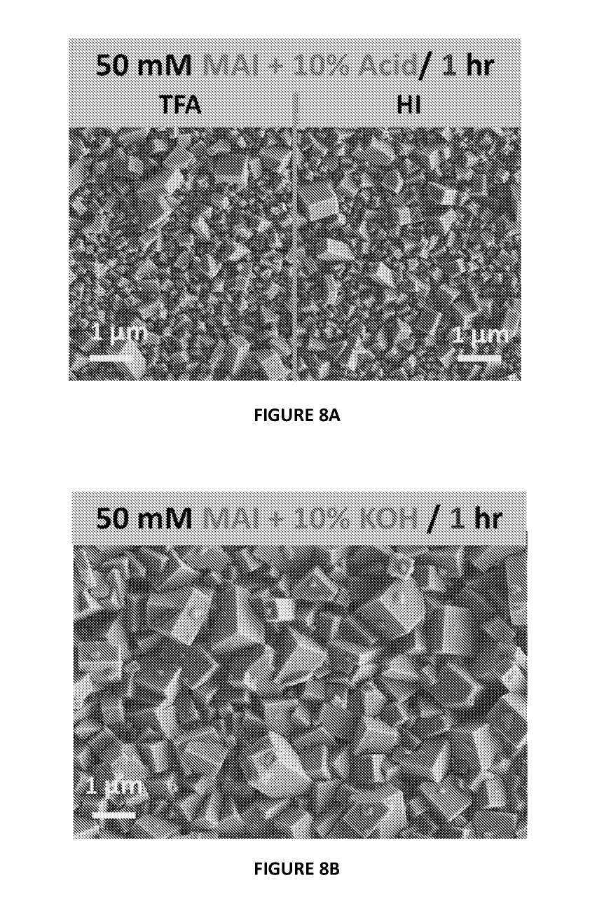

The various parameters mentioned above that affect the conversion reaction rate also affect the perovskite morphology. Plan view SEM images of films prepared by varying the solution parameters are shown (MAI concentration—FIGS. 4A-4E; acidity—FIGS. 8A, 8B; addition of elemental halogen—FIGS. 6A, 6B and 7A, 7B)

Conversion of Pb to the various perovskites entailed a volume expansion of =three times: a 120 nm film of Pb was transformed to =360 nm of perovskite.

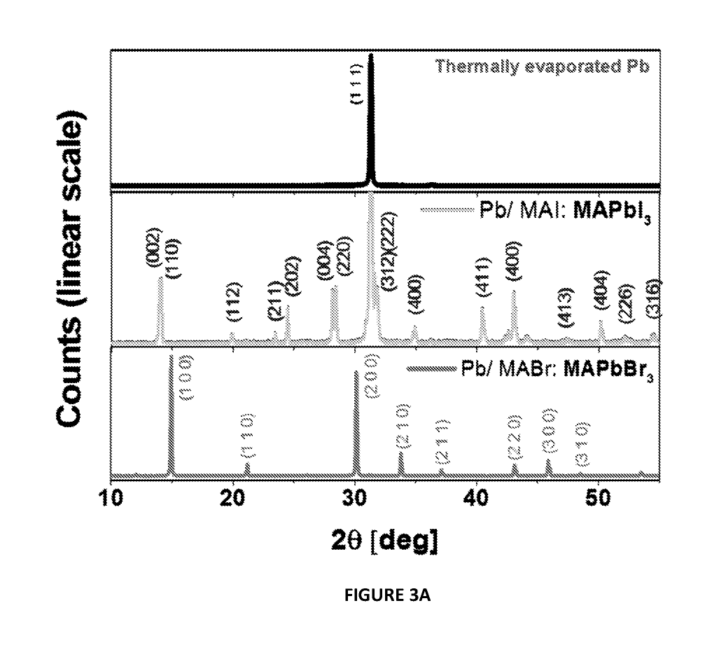

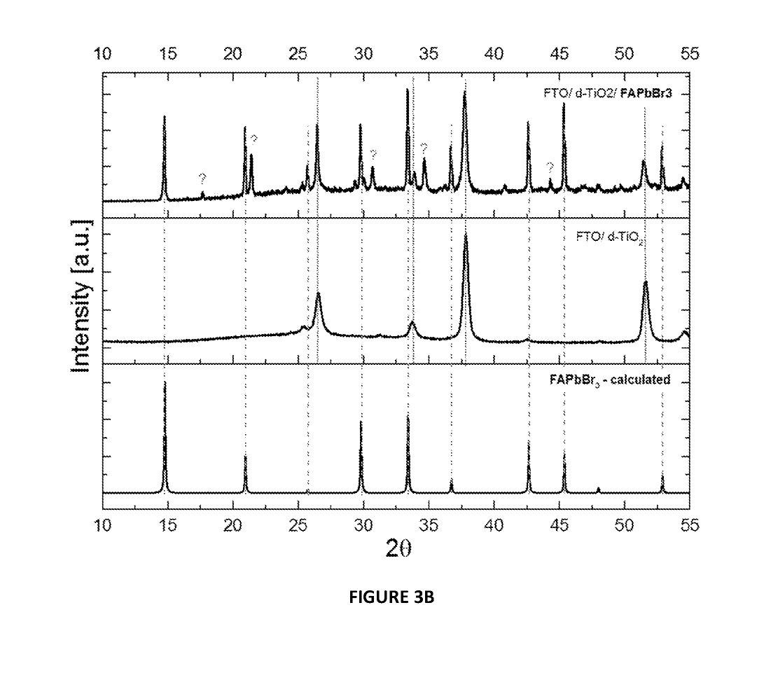

The crystal structure of the reacted films was analyzed via XRD (FIG. 3A), showing that the films are MAPbI₃ and MAPbBr₃.

In general and as might be expected, films formed by faster conversion rates are made up of smaller crystals (faster rate-faster nucleation-greater density of nuclei-smaller final crystal size). This is the case for increasing concentration of MAI (FIGS. 4A-4E) and increasing acidity (FIGS. 8A and 8B), although the rate for the higher pH (KOH) solution was not substantially different than the standard (50 mM in IPA, no other additive) MAI solution. The addition of elemental halogen had a clear effect on morphology of MAPbI₃ and MAPbBr₃ (FIGS. 6A, 6B and 7A, FB). Clearly the reaction rate was not the only factor involved in determining crystal size. It should be noted that larger crystal size does not necessarily mean better PV cells: larger crystals can often mean poorer substrate coverage, which can lead to holes in the films, resulting in shunts in the cells.

### Example 2

### The Effect of MAX (X=Br, I) Concentration on the Film Layer Morphology of MAPbX₃

The effect of MAX (X=Br, I) concentration on the film morphology is shown in

FIGS. 4A-4E for 5 different concentrations: 500 mM, 200 mM, 100 mM 50 mM and 20 mM of MAX. Two effects of increasing the salt concentration that are seen immediately, were a decrease in crystal size and increasing non-uniformity of the film. Another effect was that cracking of the films occurred at the higher concentrations. For solar cell purposes, an optimum between large crystals and good coverage (smaller crystals) occurs at concentrations of 50-70 mM.

The film morphology is very important in determining the film properties. The desired morphology depends on the intended use of the films or material.

### Example 3

### The Effect of Temperature and Solvent on Film Layer Morphology of MAPbX₃

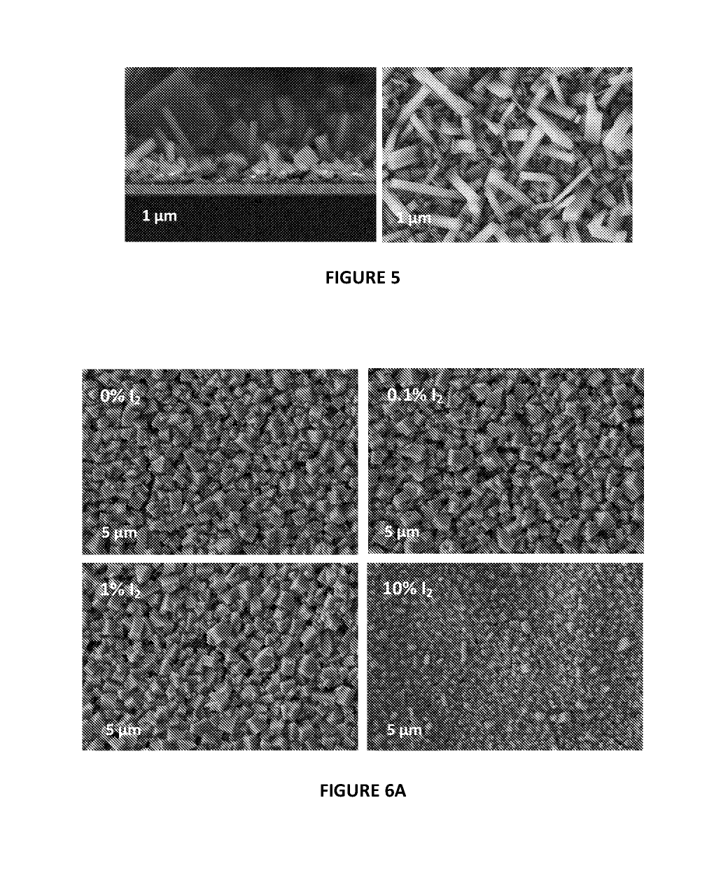

Lower temperature treatment gave better overall coverage (FIG. 7C) while higher temperature gave on average larger and more anisotropic crystals (FIG. 5). Treatment in ethanol instead of IPA gave much larger crystals but poorer coverage (FIG. 10A, 10B).

### Example 4

### The Effect of Adding Elemental Halogen to Solution on Film Layer Morphology of MAPbX₃

Addition of elemental halogens can form polyhalides with the MAX salt (X=Br or I), also affect the film layer morphology. FIGS. 6A-6C showed the effect of adding increasing amounts of elemental iodine to an IPA solution of MAI. While there was little effect of the added iodine at low concentrations, at high concentrations (10%), there was strong grain refinement, which generally led to better coverage.

The same treatment but for MAPbBr₃ and using elemental bromine also strongly affected the MAPbBr₃ but in a very different manner. Crystal growth occurred at very low concentration of bromine, at an intermediate concentration there was little apparent difference and at high concentrations, there was again crystal growth and also a change in crystal orientation (FIGS. 7A-7C). Closer observation of FIGS. 7B-7C show also an increasing tendency for formation of nanorods as the bromine concentration increased.

### Example 5

### Mixed MAPb(I,Br)₃

The method of preparation of halide perovskite and perovskite related material allowed considerable compositional flexibility. An example of this is shown in FIG. 10A. For the pure iodide and bromide, absorption onsets at 810 nm and 560 nm, respectively, correspond to those expected for these compounds. When a 50:50 mixture of MAI and MABr was used for the conversion, an absorption onset occurred at 755 nm. This corresponds to a much larger I content than Br content, not surprising since MAI reacts much faster with Pb than does MABr.

Pb was evaporated on glass and converted to MAPb(I,Br)₃ with a 50:50 (molar) mixture of MAI and MABr in IPA. FIG. 10A shows the transmission spectrum (green plot) showing an optical bandgap of 1.68 eV calculated from the spectrum and also the pure iodide (red) and bromide (green) for comparison.

### Example 6

### Conversion of Metallic Tin (Sn) to MASnI₃

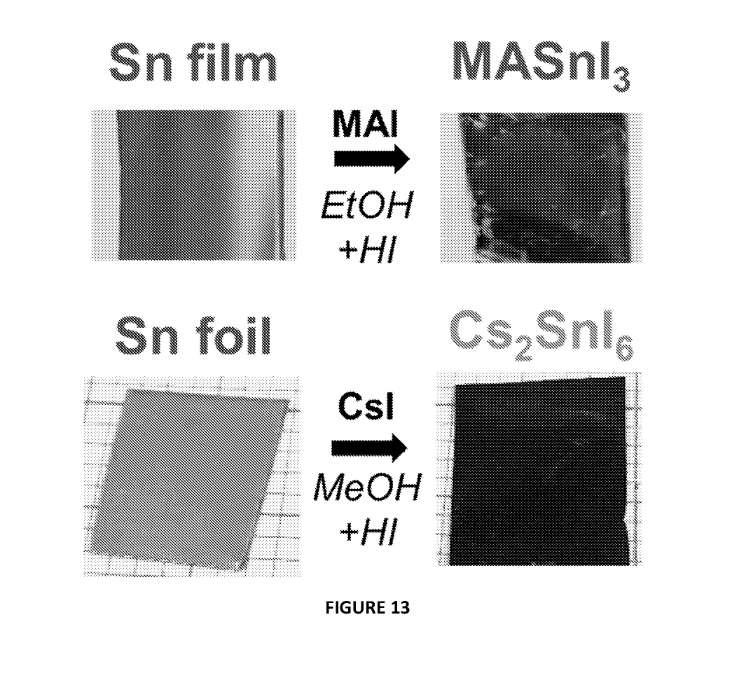

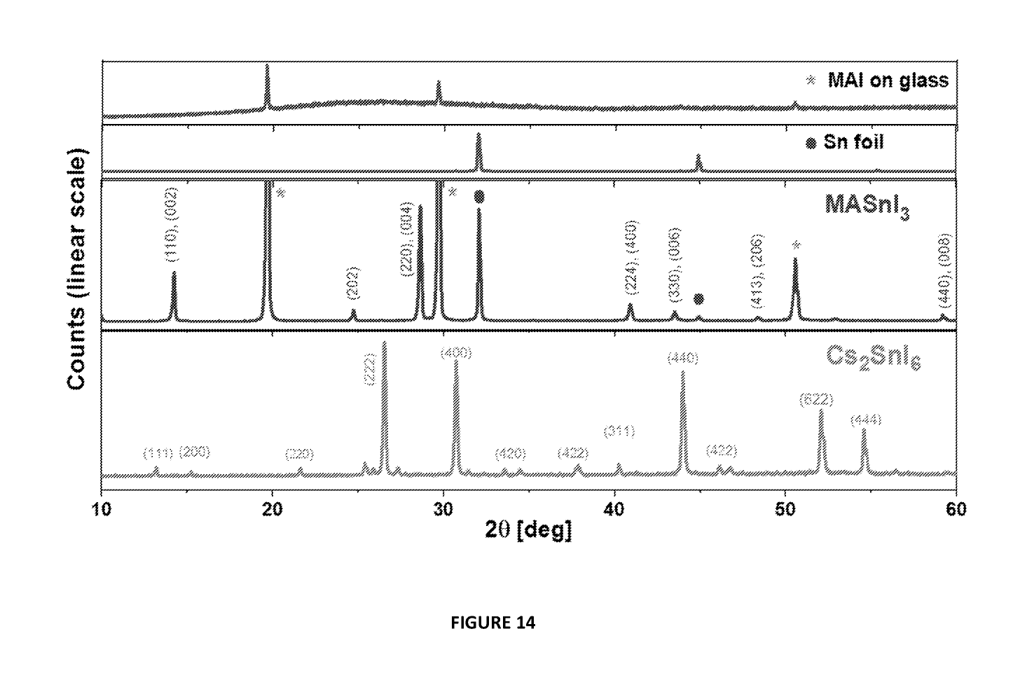

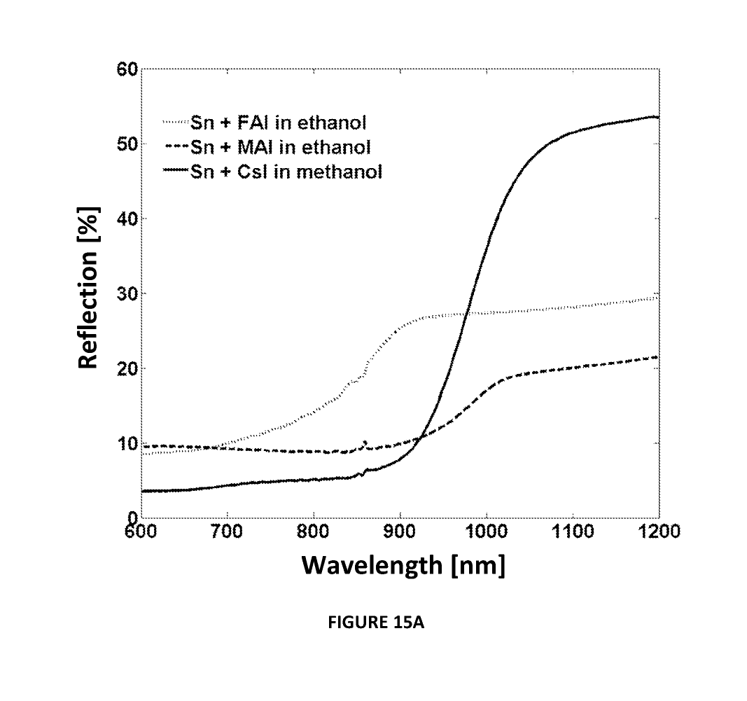

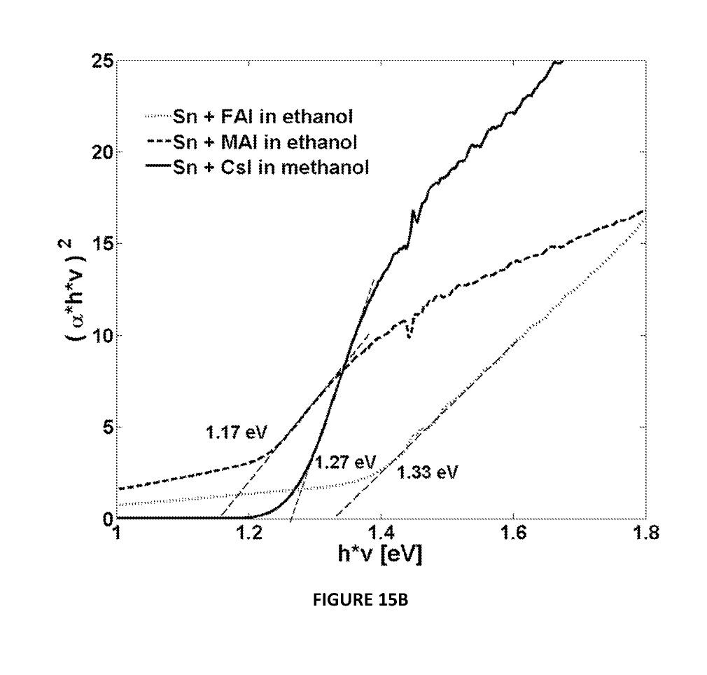

A solution of 0.5 M HI in ethanol or IPA was prepared. MAI (between 0.5 M to 1.0 M) was dissolved in the HI solution. A polished Sn film (0.125 mm thick, 99.9% Sn) was immersed in the above solution (HI+MAI) under ambient conditions for approximately 1 hr during which a black coating formed on the film (FIG. 13). XRD (FIG. 14) showed the black coating to be MASnI₃. Reflection spectroscopy (FIGS. 15A and 15B) allowed an optical bandgap estimation of 1.17 eV for this film, which is in agreement with the literature value (1.20 eV).

### Example 7

### Conversion of Metallic Tin (Sn) to FASnI₃

The procedure of Example 6 was followed, using FAI instead of MAI. From reflection spectroscopy (FIGS. 15A and 15B), an optical bandgap of 1.33 eV was measured, which agrees with the literature value (1.41 eV).

### Example 8

### Conversion of Metallic Tin (Sn) to Cs₂SnI

0.64 gr of CsI was dissolved in 0.5 M HI in methanol resulted in reaction with a Sn foil. FIG. 13 shows the conversion of Sn foil to Cs₂SnI₆ after reaction with this CsI/HI solution for ˜30 min. The conversion product is confirmed by the XRD pattern in FIG. 14. Reflection spectroscopy (FIGS. 15A and 15B) allows estimation of an optical bandgap of 1.27 eV, which agrees well with the literature value (1.26 eV).

### Example 9

### Charge Carrier Lifetimes of the Perovskite Films

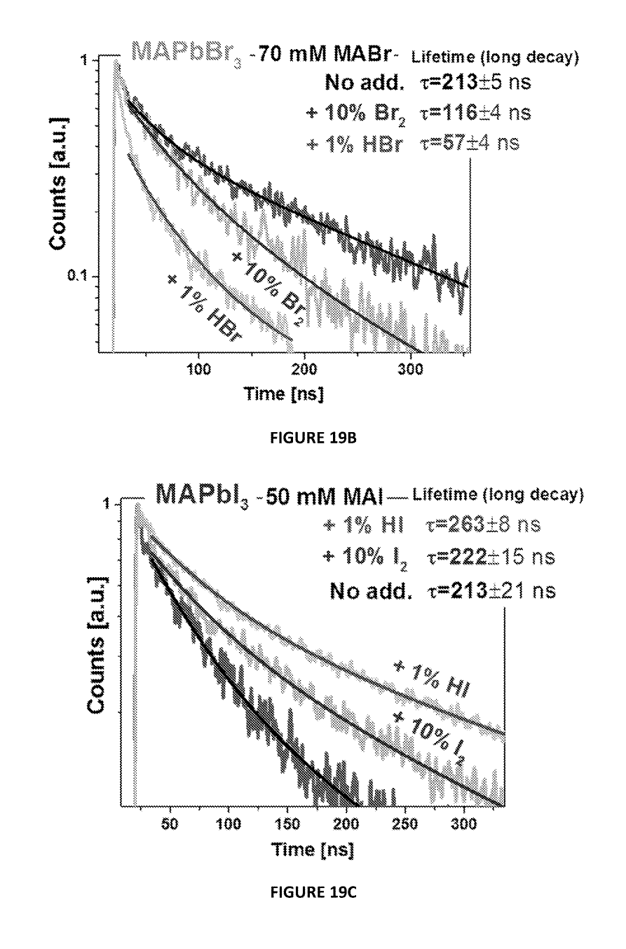

As a measure of semiconductor quality of these films, charge lifetimes were measured in the perovskite films by time resolved photoluminescence (TRPL) (FIGS. 19A-19C).—FIG. 19A shows lifetimes of 263 and 213 ns for MAPbI₃ and MAPbBr₃ respectively. These values compare favorably with films made by conventional spin coating techniques and for several values reported for single crystals. These lifetime values were dependent on the MAX solution compositions (FIGS. 19B-19C), suggesting that they can be increased even more.

### Example 10

### MAPbI₃ Photovoltaic Cell

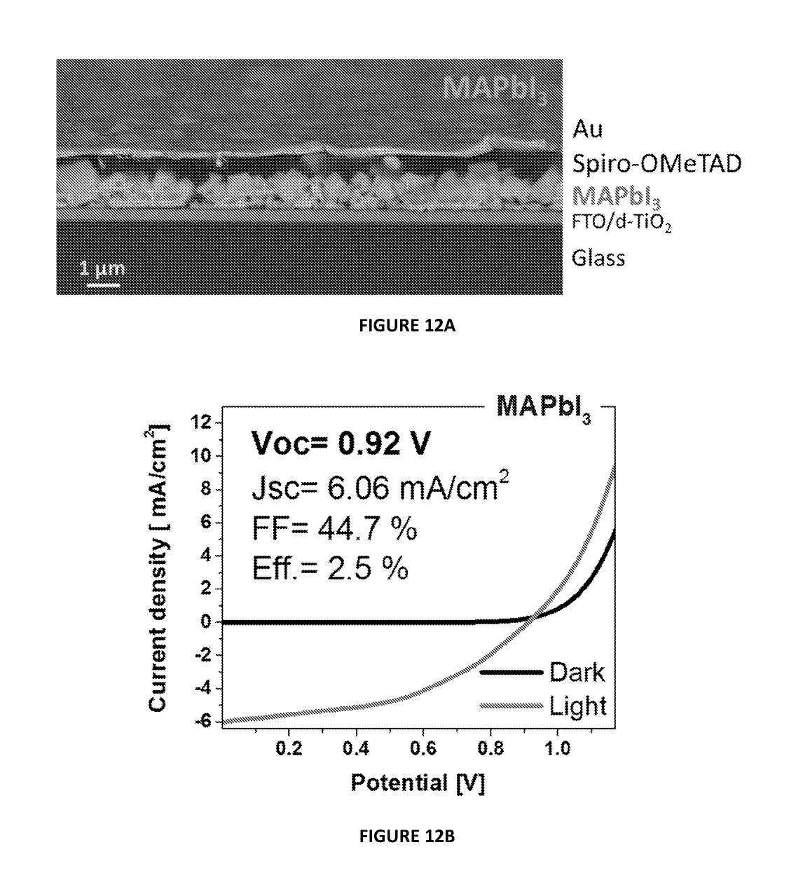

120 nm Pb was evaporated on a d-TiO₂/FTO substrate, treated with a 50 mM IPA solution of MAI for 6 h, rinsed in IPA and dried under nitrogen flow as described in Example 1. It was then coated by spin-coating with 80 mM of spiro-OMeTAD in chlorobenzene doped with 18 mM of Li-TFSI (bis(trifluoromethane)sulfonimide lithium salt) to give an average capping layer thickness of ˜0.75 μm and aged in a silica-filled sealed box overnight to allow Li-TFSI to react with oxygen to improve the electrical properties of the hole-conductor. 200 nm of gold was then thermally evaporated on the film layer through a shadow mask (0.032 cm² area) on the mentioned above samples. Note that the perovskite was not annealed in contrast to most other solution methods. X-section images of the device and the I-V curve in the dark and under illumination of 1 sun are presented in FIGS. 12A-12B.

The device gave a short current density (J_{sc}) of 6.06 mA/cm², open circuit voltage (V_{oc}) of 0.92 V and fill factor (FF) of 44.7% and overall light-to-electricity conversion efficiency of 2.5% under simulated 1 sun radiation.

### Example 11

### MAPbBr₃ Photovoltaic Cell

A photovoltaic cell was made as in Example 10 with two main differences.

1. MABr (70 mM) was used instead of MAI to form MAPbBr₃.
2. No hole conductor (spiro-OMeTAD) was used and the gold was evaporated directly on the perovskite.

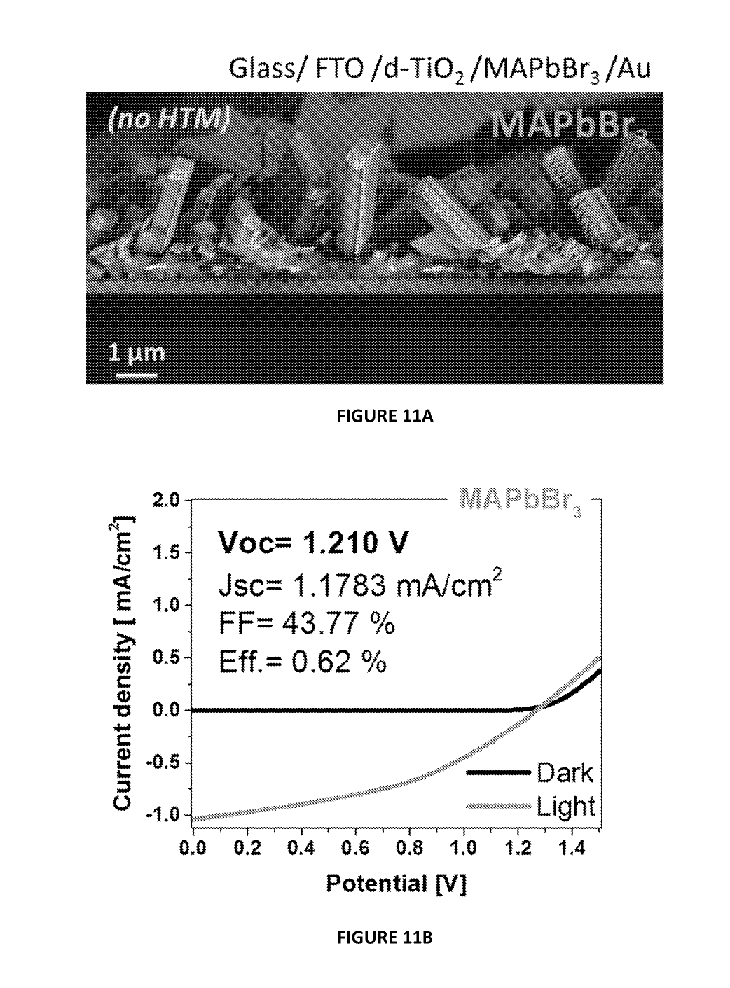

FIG. 11A shows a cross-sectional SEM image of the cell (compare with SEM image in Example 10 but without the hole conductor. The I-V curve (FIG. 11B) shows that the device gave a short current density (J_{sc}) of 1.2 mA/cm², open circuit voltage (V_{oc}) of 1.21 V and fill factor (FF) of 43.8% and overall light-to-electricity conversion efficiency of 0.62% under simulated 1 sun radiation. Note that the much higher optical bandgap of the perovskite in this cell compared with the previous example means that the current density (and overall efficiency) of the cell will be lower, but with a higher open circuit voltage. Such high voltage cells are particularly interesting for spectrally-split cells (such as tandem cells) or for photochemical reactions.

### Example 12

### Electrochemically-Assisted Conversion of Metal Pb to Halide Perovskites

The method of this invention for the preparation of halide perovskite or perovskite-related material optionally includes electrochemically-assisted conversion of the metal B layer. This option allows higher control of the conversion process, besides accelerating the conversion rate.

This example demonstrates such an electrochemically-assisted conversion. A Pb layer on glass was immersed in an IPA solution of MAI. A potentiostat was used as the power supply where the Pb layer was the working electrode and Pt spirals functioned as both counter and quasi-reference electrodes (the reference Pt issued the I⁻/I₃⁻ potential in the solution).

The formation of elemental I (or Br if MABr was used) at the Pb films during the reaction was clearly observed by a brown or yellow coloration from the iodide (FIG. 16A(i)) or bromide (FIG. 16B(i)), respectively.

From comparison of a reacted film of Pb immersed in a MAI solutions for 1 hr (FIGS. 6B, 6C, 8A and 8B) with one reacted under a bias of +0.75 V for the same time, it is clear that the reaction rate is accelerated. In the film formed without the applied voltage, the (111) Pb⁰ peak at a 2θ angle of 31.2⁰ is still detected, while for a films formed under bias, the Pb⁰ peak vanishes (FIG. 16A(ii) for MAPbI₃ and FIG. 16B(iii) for the Br analog).

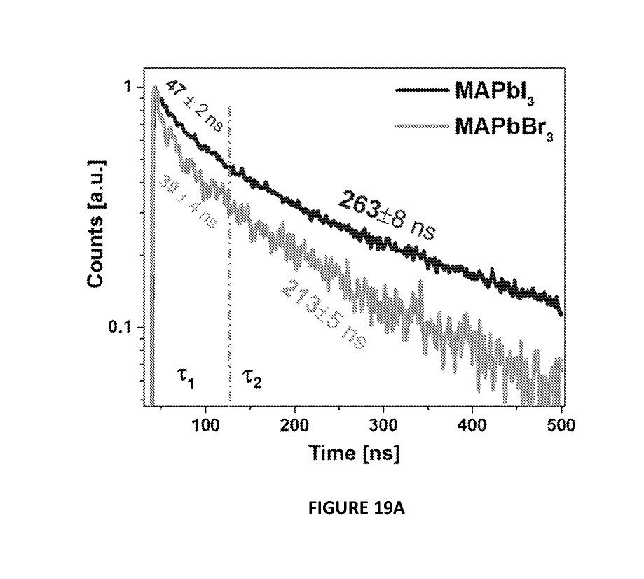

Applying an increasingly negative potential slowed the conversion reaction and at −1.0 V, a reacted perovskite film transforms back to metallic Pb (FIG. 18).

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method for the preparation of halide perovskite or perovskite-related material of formula AᵤBᵥX_{w};
wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a perovskite or perovskite-related material;
wherein the inorganic cation of A is different from the metal cation of B;
wherein said method comprises:
depositing a layer of metal or metal alloy of B on a substrate; and
treating said layer of metal or metal alloy of B with a solution or vapor comprising A and X and applying an electrical bias; wherein said solution or vapor reacts with said metal or metal alloy of B to form a halide perovskite or perovskite-related material of formula AᵤBᵥX_{w} on said solid surface;
or
depositing a layer of salt comprising A and X on a substrate; and
treating said layer of salt with a vapor of metal or metal alloy of B; wherein said metal or metal alloy of B reacts with said salt to form a halide perovskite or perovskite-related material of formula AᵤBᵥX_{w} on said solid surface.

2. The method of claim 1, wherein said method comprises:
depositing a layer of metal or metal alloy of B on a substrate; and
treating said layer of metal or metal alloy of B with a solution or vapor comprising A and X and applying an electrical bias; wherein said solution or vapor reacts with said metal or metal alloy of B to form a halide perovskite or perovskite-related material of formula AᵤBᵥX_{w} on said solid surface.

3. The method of claim 1, wherein said method comprises:
depositing a layer of a salt comprising A and X on a substrate; and
treating of said layer of salt with vapors of metal or metal alloy of B; wherein said metal or metal alloy of B reacts with said salt to form a halide perovskite or perovskite-related material of formula AᵤBᵥX_{w} on said solid surface.

4. The method of claim 1, wherein said perovskite material is represented by the following formula ABX₃, wherein
A is at least one monovalent organic cation, inorganic cation or combination thereof;
B is at least one metal cation wherein, when combined with A and X, forms a perovskite material; and
X is at least one halide anion, a pseudohalide anion or combination thereof.

5. The method of claim 1, wherein said halide perovskite-related material is represented by the following formulas
A′₂Aₙ₋₁BₙX₃ₙ₊₁ or A′Aₙ₋₁BₙX₃ₙ₊₁; n is between 1-9;
A′₂AₘBₘX₃ₘ₊₂ or A′AₘBₘX₃ₘ₊₂; m is between 1-9; or
A′₂A_{q-1}B_{q}X_{3q+1} or A′A_{q-1}B_{q}X_{3q+3}; q is between 1-9;
wherein
A is at least one monovalent organic cation, inorganic cation or combination thereof;
A′ is at least one monovalent or divalent organic cation, inorganic cation or combination thereof; wherein A and A′ are different;
B is at least one metal cation wherein, when combined with A and A′ and X, forms a halide perovskite-related material; and
X is at least one halide anion, a pseudohalide anion or combination thereof.

6. The method of claim 1, wherein A is a monovalent organic cation comprising an amine group or ammonium group, wherein said amine or ammonium group is a primary, secondary or tertiary amine or ammonium group.

7. The method of claim 1, wherein said B of the perovskite or perovskite-related material comprises a metal cation, which possess an oxidation state of (2+).

8. The method of claim 7, wherein said B of said perovskite or perovskite-related material comprises a metal cation of Group (II) metals or group (IV) metals.

9. The method of claim 1, wherein said B of said perovskite or perovskite related material comprises a mixture of metal cations, which possess an oxidation state of (+2) with metals that possess oxidation state of(+3) or (+1).

10. The method of claim 1, wherein X is F⁻, Cl⁻, Br⁻, I⁻ SCN⁻, NCS⁻, NCSe⁻, NCTe⁻, CN⁻, NC⁻, OCN⁻, NCO⁻, BH₄⁻, OSCN⁻, N₃⁻, Co(CO)₄⁻, C(NO₂)₃⁻, C(CN)₃⁻ or a combination of thereof.

11. The method of claim 1, wherein said solution or vapor comprise A and X, wherein A and X comprise ammonium and halide, ammonium and pseudohalide, alkylammonium and halide, alkylamidinium and halide, alkylamidinium and pseudohalide, formamidinium, and halide, alkylammonium and pseudohalide, formamidinium and pseudohalide, an organic cation comprising an amine and halide, an organic cation comprising an amine and pseudohalide, a monovalent metal cation and halide, monovalent metal cation and pseudohalide; divalent metal cation and halide, divalent metal cation and pseudohalide or combination thereof.

12. The method of claim 1, wherein said method, optionally further comprises addition of an external additive to said solution or vapor, wherein said external additive comprises a halogen (F₂, Cl₂, Br₂, I₂), HI, HCl, HBr, HF, HCN, S(CN)₂, haloalkane, haloarene, haloheteroarene, halocycloalkane, reducing agents, halogen salts or combination thereof.

13. The method of claim 1, wherein said method, optionally further comprises addition of an external additive to said salt, wherein said external additive comprises a halogen (F₂, Cl₂, Br₂, I₂), HI, HCl, HBr, HF, HCN, S(CN)₂, haloalkane, haloarene, haloheteroarene, halocycloalkane, reducing agents, halogen salts or combination thereof

14. The method of claim 1, wherein said perovskite or perovskite-related material is MAPbI₃, MAPbBr₃, MAPb(I,Br)₃, FAPbI₃, FAPbBr₃, FAPb(I,Br)₃, CsPbI₃, CsPbBr₃, CsPb(I,Br)₃ or (Cs,FA)Pb(I,Br)₃.

15. The method of claim 1, wherein said solution with compounds of A and X is optionally heated.

16. (canceled)

17. A halide perovskite or perovskite-related materials prepared according to the method of claim 1.

18. An optoelectronic device comprising a halide perovskite or perovskite-related material of formula AᵤBᵥX_{w};
wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite-related materials;
wherein the inorganic cation of A is different from the metal cation of B;
wherein said perovskite or perovskite-related material of formula AᵤBᵥX_{w} is prepared according to the method of claim 1.

19. The optoelectronic device of claim 18, wherein said halide perovskite-related material is represented by the following formulas
A′₂Aₙ₋₁BₙX₃ₙ₊₁ or A′Aₙ₋₁BₙX₃ₙ₊₁; n is between 1-9;
A′₂AₘBₘX₃ₘ₊₂ or A′AₘBₘX₃ₘ₊₂; m is between 1-9; or
A′₂A_{q-1}B_{q}X_{3q+1} or A′A_{q-1}B_{q}X_{3q+3}; q is between 1-9;
wherein
A is at least one monovalent organic cation, inorganic cation or combination thereof;
A′ is at least one monovalent or divalent organic cation, inorganic cation or combination thereof; wherein A and A′ are different;
B is at least one metal cation wherein, when combined with A and A′ and X, forms a perovskite related material; and
X is at least one halide anion, a pseudohalide anion or combination thereof.

20. A photovoltaic cell comprising a halide perovskite or perovskite-related material of formula AᵤBᵥX_{w};
wherein:
A is at least one monovalent or divalent organic cation, inorganic cation or combination thereof;
X is at least one halide anion, a pseudohalide anion or combination thereof;
u is between 1-10;
v is between 1-10;
w is between 3-30;
B is at least one metal cation wherein, when combined with A and X, forms a halide perovskite or perovskite-related material;
wherein the inorganic cation of A is different from the metal cation of B; wherein said perovskite or perovskite-related material of formula AᵤBᵥX_{w} is prepared according to the method of claim 1.

21. The photovoltaic cell of claim 20, wherein said perovskite-related material is represented by the following formulas
A′₂Aₙ₋₁BₙX₃ₙ₊₁ or A′Aₙ₋₁BₙX₃ₙ₊₁; n is between 1-9;
A′₂AₘBₘX₃ₘ₊₂ or A′AₘBₘX₃ₘ₊₂; m is between 1-9; or
A′₂A_{q-1}B_{q}X_{3q+1} or A′A_{q-1}B_{q}X_{3q+3}; q is between 1-9;
A is at least one monovalent organic cation, inorganic cation or combination thereof;
A′ is at least one monovalent or divalent organic divalent organic cation, inorganic cation or combination thereof; wherein A and A′ are different;
B is at least one metal cation wherein, when combined with A and A′ and X, forms a perovskite-related material; and
X is at least one halide anion, a pseudohalide anion or combination thereof.
